(19) United States
(12) Patent Application Publication
(10) Pub. No.: US 2024/0313043 A1
(43) Pub. Date: Sep. 19, 2024

(54) INSULATION CHIP AND SIGNAL TRANSMISSION DEVICE

(71) Applicant: ROHM CO., LTD., Kyoto-shi (JP)

(72) Inventor: Bungo TANAKA, Kyoto-shi (JP)

(21) Appl. No.: 18/675,658

(22) Filed: May 28, 2024

Related U.S. Application Data
(63) Continuation of application No. PCT/JP2022/043766, filed on Nov. 28, 2022.

(30) Foreign Application Priority Data
Dec. 1, 2021 (JP) 2021-195484

(51) Int. Cl. H01L 25/16; H01L 23/00; H01L 23/14; H01L 29/92

(52) U.S. Cl. CPC H01L 28/75; H01L 23/147; H01L 24/32; H01L 24/48; H01L 25/162; H01L 28/86; H01L 29/92; H01L 2224/32235; H01L 2224/48248

(57) ABSTRACT

An insulation chip includes an element insulation layer, a first capacitor, and a second capacitor. The first capacitor includes a first front surface-side electrode plate and a first back surface-side electrode plate that are disposed opposite each other. The second capacitor includes a second front surface-side electrode plate and a second back surface-side electrode plate. The second front surface-side electrode plate and the second back surface-side electrode plate are opposed to each other. In the element insulation layer, the first back surface-side electrode plate and the second back surface-side electrode plate are electrically connected. This signal transmission device includes: a first chip including a first circuit; the insulation chip; and a second chip including a second circuit configured to perform at least one of transmission and reception of a signal with the first circuit via the insulation chip.

### BACKGROUND

The present disclosure relates to an insulation chip and a signal transmission device.

A known example of a signal transmission device is an insulated gate driver that applies a gate voltage to the gate of a switching element such as a transistor (for example, refer to JP 2020-25102 A).

### BRIEF DESCRIPTION OF DRAWINGS

FIG. 1 is a schematic circuit diagram showing a circuit configuration of a signal transmission device in a first embodiment.

FIG. 2 is a schematic cross-sectional view showing a cross-sectional structure of the signal transmission device shown in FIG. 1.

FIG. 3 is a schematic plan view showing a planar structure of an insulation chip in the signal transmission device shown in FIG. 2.

FIG. 4 is a schematic cross-sectional view showing a cross-sectional structure of the insulation chip shown in FIG. 3 taken along a plane orthogonal to the thickness-wise direction of the insulation chip.

FIG. 5 is a schematic cross-sectional view showing a cross-sectional structure of the insulation chip taken in line F5-F5 in FIG. 3.

FIG. 6 is a schematic cross-sectional view showing a cross-sectional structure of the insulation chip taken in line F6-F6 in FIG. 3.

FIG. 7 is a schematic plan view showing a planar structure of a portion of an insulation chip in a comparative example.

FIG. 8 is a schematic cross-sectional view showing a cross-sectional structure of the insulation chip in the comparative example taken in line F8-F8 in FIG. 7.

FIG. 9 is a schematic cross-sectional view showing a cross-sectional structure of a signal transmission device in a modified example.

FIG. 10 is a schematic plan view showing a planar structure of an insulation chip in a modified example.

FIG. 11 is a schematic plan view showing a planar structure of an insulation chip in a modified example.

FIG. 12 is a schematic plan view showing a planar structure of an insulation chip in a modified example.

FIG. 13 is a schematic cross-sectional view showing a cross-sectional structure of the insulation chip in the modified example shown in FIG. 12 taken along a plane orthogonal to the thickness-wise direction of the insulation chip.

FIG. 14 is a schematic cross-sectional view showing a cross-sectional structure of an insulation chip in a modified example.

FIG. 15 is a schematic cross-sectional view showing a cross-sectional structure of an insulation chip in a modified example.

### DETAILED DESCRIPTION

Embodiments of an insulation chip and a signal transmission device according to the present disclosure will be described below with reference to the drawings. In the drawings, components may not be drawn to scale for simplicity and clarity of illustration. In a cross-sectional view, hatching may be omitted to facilitate understanding. The accompanying drawings only illustrate embodiments of the present disclosure and are not intended to limit the present disclosure.

The following detailed description includes exemplary embodiments of a device, a system, and a method according to the present disclosure. The detailed description is illustrative and is not intended to limit embodiments of the present disclosure or the application and use of the embodiments.

### Embodiments

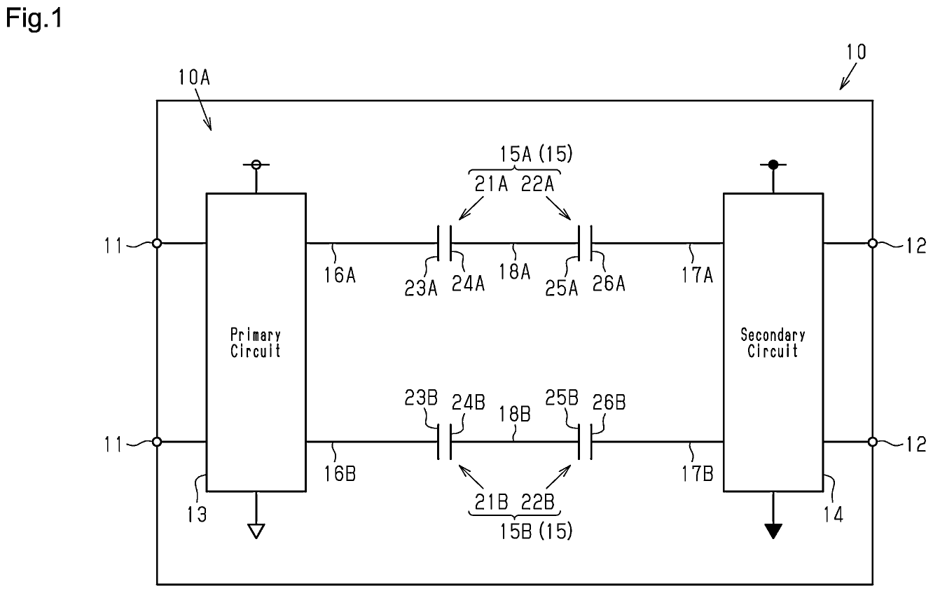

The structures of embodiments of an insulation chip and a signal transmission device will now be described with reference to FIGS. 1 to 6. FIG. 1 is a simplified diagram showing an example of a circuit configuration of a signal transmission device 10.

### Circuit Configuration of Signal Transmission Device

As shown in FIG. 1, the signal transmission device 10 transmits a pulse signal while electrically insulating primary terminals 11 from secondary terminals 12. The signal transmission device 10 is a digital isolator and is, for example, an AC/DC converter, a gate driver, or an electronic component included in the AC/DC converter or the gate driver. The signal transmission device 10 includes a signal transmission circuit 10A that includes a primary circuit 13 electrically connected to the primary terminals 11, a secondary circuit 14 electrically connected to the secondary terminals 12, and a capacitor 15 electrically connecting the primary circuit 13 and the secondary circuit 14. In the present embodiment, the primary circuit 13 corresponds to a “first circuit,” and the secondary circuit 14 corresponds to a “second circuit.”

The primary circuit 13 is configured to be actuated by application of a first voltage. In an example, the primary circuit 13 is electrically connected to an external controller (not shown).

The secondary circuit 14 is configured to be actuated by application of a second voltage that differs from the first voltage. In an example, the second voltage is higher than the first voltage. The first voltage and the second voltage are direct current voltages. In an example, the secondary circuit 14 is electrically connected to a drive circuit that is a subject controlled by the controller. An example of the drive circuit is a switching circuit.

The signal transmission device 10 is configured so that when the primary circuit 13 receives a control signal from the controller through the primary terminals 11, the signal is transmitted from the primary circuit 13 to the secondary circuit 14 through the capacitor 15, and the secondary circuit 14 outputs the signal to the drive circuit through the secondary terminals 12. The signal transmission device 10 is configured to transmit a signal from the primary circuit 13 toward the secondary circuit 14 through the capacitor 15.

In the signal transmission circuit 10A, the primary circuit 13 and the secondary circuit 14 are electrically insulated by the capacitor 15. More specifically, while restricting transmission of a direct current voltage between the primary circuit 13 and the secondary circuit 14, the capacitor 15 allows transmission of a pulse signal.

That is, the state in which the primary circuit 13 and the secondary circuit 14 are insulated refers to a state in which transmission of a direct current voltage between the primary circuit 13 and the secondary circuit 14 is blocked, whereas transmission of a pulse signal from the primary circuit 13 to the secondary circuit 14 is allowed. Thus, the secondary circuit 14 is configured to receive a signal from the primary circuit 13.

The insulation voltage of the signal transmission device 10 is, for example, in a range of 2500 Vrms to 7500 Vrms. In the present embodiment, the insulation voltage of the signal transmission device 10 is approximately 5700 Vrms. However, the insulation voltage of the signal transmission device 10 is not limited to this value and may be any specific numerical value. As shown in FIG. 1, in the present embodiment, the primary circuit 13 and the secondary circuit 14 are individually provided with ground.

The circuit configuration of the signal transmission device 10 will now be described in detail.

In the present embodiment, the signal transmission device 10 includes two capacitors 15 corresponding to two types of signals transmitted from the primary circuit 13 toward the secondary circuit 14. More specifically, the signal transmission device 10 includes a capacitor 15 that is used to transmit a first signal from the primary circuit 13 to the secondary circuit 14 and a capacitor 15 that is used to transmit a second signal from the primary circuit 13 to the secondary circuit 14. In the present embodiment, the first signal includes information about a rising edge of an external signal that is input to the signal transmission device 10. The second signal includes information about a falling edge of the external signal. The first signal and the second signal generate a pulse signal. Hereinafter, for the sake of brevity, the capacitor 15 used to transmit the first signal is referred to as a “capacitor 15A.” The capacitor 15 used to transmit the second signal is referred to as a “capacitor 15B.”

The signal transmission device 10 includes primary signal lines 16A and 16B and secondary signal lines 17A and 17B.

The primary signal line 16A is configured to connect the primary circuit 13 and the capacitor 15A and transmit a first signal from the primary circuit 13 to the capacitor 15A. The primary signal line 16B is configured to connect the primary circuit 13 and the capacitor 15B and transmit a second signal from the primary circuit 13 to the capacitor 15B.

The secondary signal line 17A is configured to connect the capacitor 15A and the secondary circuit 14 and transmit a first signal from the capacitor 15A to the secondary circuit 14. The secondary signal line 17B is configured to connect the capacitor 15B and the secondary circuit 14 and transmit a second signal from the capacitor 15B to the secondary circuit 14.

As described above, the first signal is transmitted from the primary circuit 13 to the secondary circuit 14 sequentially through the primary signal line 16A, the capacitor 15A, and the secondary signal line 17A. The second signal is transmitted from the primary circuit 13 to the secondary circuit 14 sequentially through the primary signal line 16B, the capacitor 15B, and the secondary signal line 17B.

While transmitting the first signal from the primary circuit 13 to the secondary circuit 14, the capacitor 15A electrically insulates the primary circuit 13 from the secondary circuit 14. The capacitor 15A includes a first capacitor 21A and a second capacitor 22A connected in series to each other. The first capacitor 21A is connected to the primary signal line 16A. The second capacitor 22A is connected to the secondary signal line 17A. In the present embodiment, the first capacitor 21A and the second capacitor 22A correspond to a “first signal capacitor.”

The first capacitor 21A includes a first electrode 23A and a second electrode 24A. The first electrode 23A is connected to the primary signal line 16A. The second capacitor 22A includes a first electrode 25A and a second electrode 26A. The second electrode 24A of the first capacitor 21A and the first electrode 25A of the second capacitor 22A are connected by a connection signal line 18A. The second electrode 26A is connected to the secondary signal line 17A.

While transmitting the second signal from the primary circuit 13 to the secondary circuit 14, the capacitor 15B electrically insulates the primary circuit 13 from the secondary circuit 14. The capacitor 15B includes a first capacitor 21B and a second capacitor 22B connected in series to each other. The first capacitor 21B is connected to the primary signal line 16B. The second capacitor 22B is connected to the secondary signal line 17B. In the present embodiment, the first capacitor 21B and the second capacitor 22B correspond to a “second signal capacitor.”

The first capacitor 21B includes a first electrode 23B and a second electrode 24B. The first electrode 23B is connected to the primary signal line 16B. The second capacitor 22B includes a first electrode 25B and a second electrode 26B. The second electrode 24B of the first capacitor 21B and the first electrode 25B of the second capacitor 22B are connected by a connection signal line 18B. The second electrode 26B is connected to the secondary signal line 17B.

In the present embodiment, the insulation voltage of the capacitors 15A and 15B is, for example, in a range of 2500 Vrms to 7500 Vrms. The insulation voltage of the capacitors 15A and 15B may be in a range of 2500 Vrms to 5700 Vrms. However, the insulation voltage of the capacitors 15A and 15B is not limited to these values and may be any specific numerical value.

### Internal Configuration of Signal Transmission Device

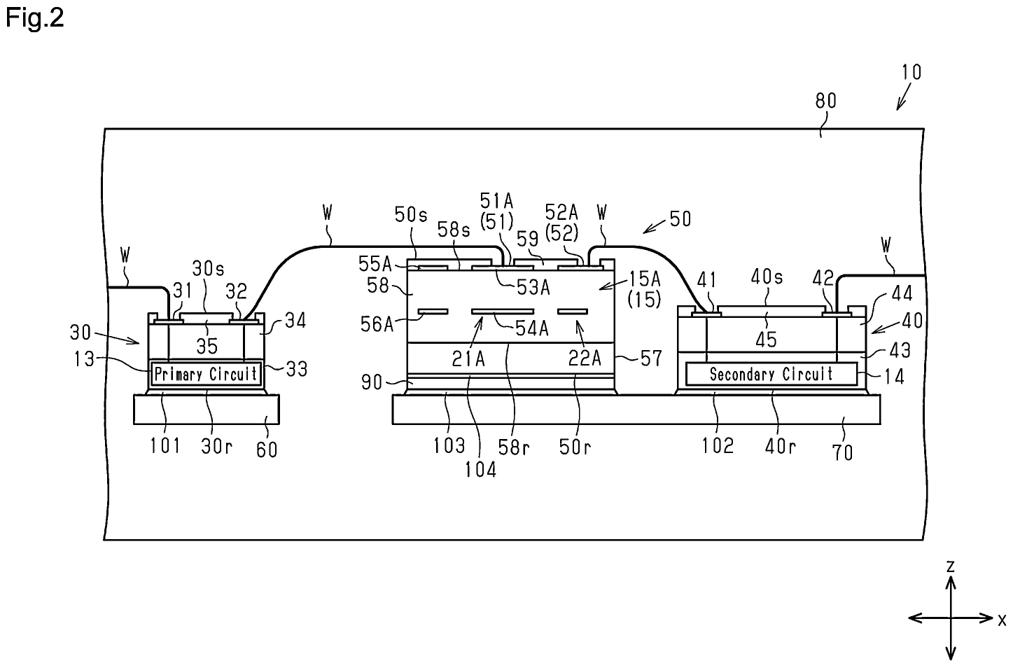

FIG. 2 is a schematic diagram showing an example of a cross-sectional structure of an internal configuration of a portion of the signal transmission device 10. As shown in FIG. 2, the signal transmission device 10 is a semiconductor device including multiple semiconductor chips arranged in a single package. Although not shown in the drawings, the package of the signal transmission device 10 is, for example, of a small outline (SO) type and, in the present embodiment, is a small outline package (SOP). The package type of the signal transmission device 10 may be changed in any manner.

The signal transmission device 10 includes the multiple semiconductor chips, namely, a first chip 30, a second chip 40, and an insulation chip 50. The signal transmission device 10 further includes a primary die pad 60 on which the first chip 30 is mounted, a secondary die pad 70 on which the second chip 40 is mounted, and an encapsulation resin 80 encapsulating the die pads 60 and 70 and the chips 30, 40, and 50. In the present embodiment, the primary die pad 60 corresponds to a “first mount frame,” and the secondary die pad 70 corresponds to a “mount frame” or a “second mount frame.”

The encapsulation resin 80 is formed from an electrically-insulative resin material and is, for example, formed from a black epoxy resin. The encapsulation resin 80 has the form of a rectangular plate having a thickness-wise direction conforming to the z-direction.

The primary die pad 60 and the secondary die pad 70 are each formed from a conductive material. In the present embodiment, the die pads 60 and 70 are formed from a material including copper (Cu). Alternatively, the die pads 60 and 70 may be formed from a material including a different metal such as aluminum (Al). Furthermore, the material of the die pads 60 and 70 is not limited to a conductive material. In an example, the die pads 60 and 70 may be formed from ceramics such as alumina. That is, the die pads 60 and 70 may be formed from an electrically-insulative material. In the present embodiment, the die pads 60 and 70 are not exposed from the encapsulation resin 80.

As viewed in the z-direction, the primary die pad 60 and the secondary die pad 70 are separated from each other and arranged next to each other. As viewed in the z-direction, the arrangement direction of the primary die pad 60 and the secondary die pad 70 is referred to as an x-direction. As viewed in the z-direction, a direction orthogonal to the x-direction is referred to as a y-direction. The primary die pad 60 and the secondary die pad 70 are each flat. In the present embodiment, the secondary die pad 70 is greater than the primary die pad 60 in the dimension in the x-direction.

In the present embodiment, the insulation chip 50 is mounted on the secondary die pad 70. More specifically, the insulation chip 50 and the second chip 40 are mounted on the secondary die pad 70. The second chip 40 and the insulation chip 50 are separated from each other in the x-direction. Thus, the chips 30, 40, and 50 are separated from each other in the x-direction. In the present embodiment, the chips 30, 40, and 50 are arranged in the x-direction in the order of the first chip 30, the insulation chip 50, and the second chip 40 in a direction from the primary die pad 60 toward the secondary die pad 70. That is, the insulation chip 50 is located between the first chip 30 and the second chip 40 in the x-direction.

The die pads 60 and 70 need to be separated from each other so that the signal transmission device 10 is set to a predetermined insulation voltage. In the present embodiment, as viewed in the z-direction, the distance between the primary die pad 60 and the secondary die pad 70 is greater than the distance between the second chip 40 and the insulation chip 50 in the x-direction. Therefore, as viewed in the z-direction, the distance between the first chip 30 and the insulation chip 50 in the x-direction is greater than the distance between the second chip 40 and the insulation chip 50 in the x-direction. In other words, the insulation chip 50 is located closer to the second chip 40 than to the first chip 30.

The first chip 30 includes a first substrate 33 on which the primary circuit 13 is formed. The first substrate 33 is, for example, a semiconductor substrate. In an example, the semiconductor substrate is formed from a material including silicon (Si). An interconnect layer 34 is formed on the first substrate 33. The interconnect layer 34 includes insulation films stacked in the z-direction, metal layers arranged between ones of the insulation films that are adjacent to each other in the z-direction, and vias connecting ones of the metal layers located at different positions in the z-direction. The metal layers and the vias form a wiring pattern of the first chip 30. The metal layers and the vias are, for example, electrically connected to the primary circuit 13. A protective film 35 is formed on the interconnect layer 34 to protect the interconnect layer 34. The protective film 35 is formed from an electrically-insulative material.

The first chip 30 includes a chip front surface 30s and a chip back surface 30r facing opposite directions in the z-direction. The first substrate 33 includes the chip back surface 30r. The protective film 35 includes the chip front surface 30s. The chip back surface 30r faces the primary die pad 60. First electrode pads 31 and second electrode pads 32 are arranged on a portion of the first chip 30 located toward the chip front surface 30s. More specifically, the electrode pads 31 and 32 are exposed from the chip front surface 30s. The protective film 35 covers the electrode pads 31 and 32. The protective film 35 includes openings that expose the electrode pads 31 and 32. The electrode pads 31 and 32 are, for example, electrically connected to the primary circuit 13 by the interconnect layer 34.

The first electrode pads 31 and the second electrode pads 32 are formed on a front surface of the interconnect layer 34. The front surface of the interconnect layer 34 refers to a surface of the interconnect layer 34 facing the same direction as the chip front surface 30s. As viewed in the z-direction, the first electrode pads 31 are arranged on the chip front surface 30s at a side opposite from the insulation chip 50 with respect to the center of the chip front surface 30s in the x-direction. Although not shown, the electrode pads 31 are separated from each other in the y-direction. The second electrode pads 32 are arranged on a portion of the chip front surface 30s located toward the insulation chip 50 with respect to the center of the chip front surface 30s in the x-direction. Although not shown, the second electrode pads 32 are separated from each other in the y-direction.

As shown in FIG. 2, the first chip 30 is bonded to the primary die pad 60 by a first bonding material 101. The first bonding material 101 is located between the chip back surface 30r of the first chip 30 and the primary die pad 60. The first bonding material 101 is a conductive bonding material such as solder paste or silver (Ag) paste.

The first bonding material 101 bonds the first substrate 33 of the first chip 30 and the primary die pad 60 and thus electrically connects the first substrate 33 and the primary die pad 60. Thus, the primary circuit 13 is electrically connected to the primary die pad 60 by the first bonding material 101. In the present embodiment, the primary die pad 60 forms ground. Thus, the primary circuit 13 is electrically connected to the ground.

The content of the first bonding material 101 may be changed in any manner and be, for example, an insulative bonding material. In this case, the primary circuit 13 may be electrically connected to the primary die pad 60 by a component (e.g., wire) other than the first bonding material 101.

The second chip 40 includes a second substrate 43 on which the secondary circuit 14 is formed. The second substrate 43 is, for example, a semiconductor substrate. In an example, the semiconductor substrate is formed from a material including Si. An interconnect layer 44 is formed on the second substrate 43. The interconnect layer 44 includes insulation films stacked in the z-direction, metal layers arranged between ones of the insulation films that are adjacent to each other in the z-direction, and vias connecting ones of the metal layers located at different positions in the z-direction. The metal layers and the vias from a wiring pattern of the second chip 40. The metal layers and the vias are, for example, electrically connected to the secondary circuit 14. A protective film 45 is formed on the interconnect layer 44 to protect the interconnect layer 44. The protective film 45 is formed from an electrically-insulative material.

The second chip 40 includes a chip front surface 40s and a chip back surface 40r facing opposite directions in the z-direction. The second substrate 43 includes the chip back surface 40r. The protective film 45 includes the chip front surface 40s. The chip back surface 40r faces the secondary die pad 70. The chip back surface 40r faces the same direction as the chip back surface 30r of the first chip 30. The chip front surface 40s faces the same direction as the chip front surface 30s of the first chip 30. First electrode pads 41 and second electrode pads 42 are arranged on a portion of the second chip 40 located toward the chip front surface 40s. More specifically, the electrode pads 41 and 42 are exposed from the chip front surface 40s. The protective film 45 covers the electrode pads 41 and 42. The protective film 45 includes openings that expose the electrode pads 41 and 42. The electrode pads 41 and 42 are, for example, electrically connected to the secondary circuit 14 by the interconnect layer 44.

The first electrode pads 41 and the second electrode pads 42 are formed on a front surface of the interconnect layer 44. The front surface of the interconnect layer 44 refers to a surface of the interconnect layer 44 facing the same direction as the chip front surface 40s. As viewed in the z-direction, the first electrode pads 41 are arranged on a portion of the chip front surface 40s located toward the insulation chip 50 with respect to the center of the chip front surface 40s in the x-direction. Although not shown, the first electrode pads 41 are separated from each other in the y-direction. The second electrode pads 42 are arranged on the chip front surface 40s at a side opposite from the insulation chip 50 with respect to the center of the chip front surface 40s in the x-direction. Although not shown, the second electrode pads 42 are separated from each other in the y-direction.

The second chip 40 is bonded to the secondary die pad 70 by a second bonding material 102. More specifically, the second bonding material 102 is located between the chip back surface 40r and the secondary die pad 70. The second bonding material 102 bonds the chip back surface 40r and the secondary die pad 70. The second bonding material 102 is a conductive bonding material such as solder paste or Ag paste. In the present embodiment, the second bonding material 102 has, for example, the same content as the first bonding material 101.

The content of the second bonding material 102 may be changed in any manner and be, for example, a conductive bonding material that differs from the material of the first bonding material 101. The second bonding material 102 may be an insulative bonding material. In this case, the secondary circuit 14 may be electrically connected to the secondary die pad 70 by a component (e.g., wire) other than the second bonding material 102.

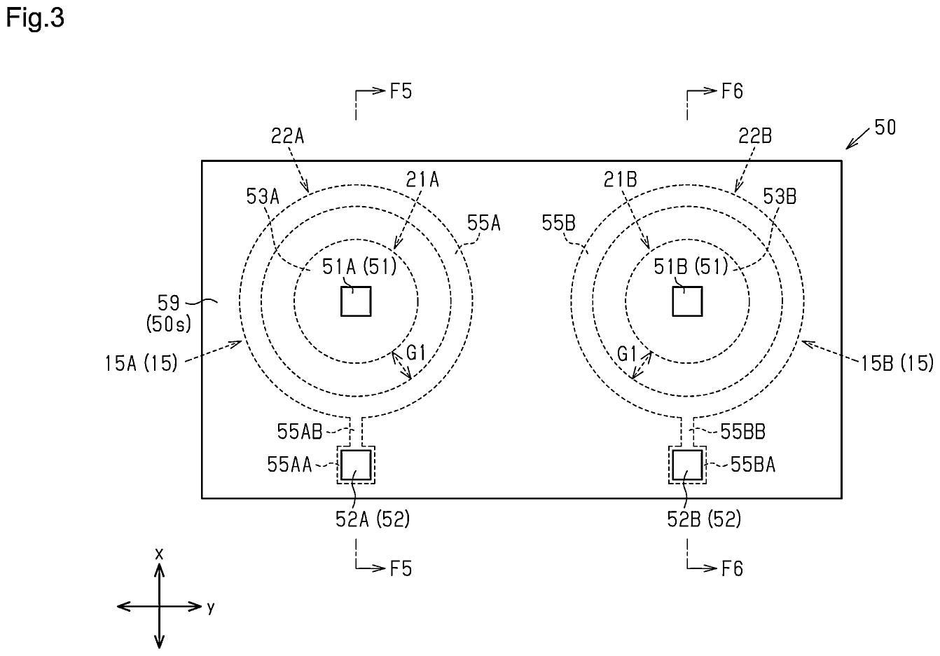

The insulation chip 50 includes the capacitors 15A and 15B (refer to FIG. 1). As shown in FIG. 3, as viewed in the z-direction, the insulation chip 50 is rectangular and includes long sides and short sides. In the present embodiment, as viewed in the z-direction, the insulation chip 50 is mounted on the secondary die pad 70 so that the long sides extend in the y-direction and the short sides extend in the x-direction.

As shown in FIG. 2, the insulation chip 50 includes a chip front surface 50s and a chip back surface 50r facing opposite directions in the z-direction. The chip back surface 50r faces the secondary die pad 70. More specifically, the chip back surface 50r faces the same direction as the chip back surface 40r of the second chip 40. The chip front surface 50s faces the same direction as the chip front surface 40s of the second chip 40.

The insulation chip 50 includes multiple (in the present embodiment, two) first electrode pads 51 and multiple (in the present embodiment, two) second electrode pads 52. The electrode pads 51 and 52 are arranged toward the chip front surface 50s. More specifically, as viewed in the z-direction, the electrode pads 51 and 52 are exposed from the chip front surface 50s.

The first electrode pads 51 are arranged on a portion of the chip front surface 50s located toward the first chip 30 with respect to the center of the chip front surface 50s in the x-direction. The second electrode pads 52 are arranged on a portion of the chip front surface 50s located toward the second chip 40 with respect to the center of the chip front surface 50s in the x-direction.

Wires W are connected to each of the first chip 30, the second chip 40, and the insulation chip 50. The first chip 30 and the insulation chip 50 are electrically connected by the wires W. The second chip 40 and the insulation chip 50 are electrically connected by the wires W. Each wire W is a bonding wire formed by a wire bonder and is, for example, formed from a conductor such as gold (Au), Al, Cu, or the like.

The first electrode pads 31 of the first chip 30 are separately connected by wires W to primary leads, which are not shown. The primary leads are parts forming the primary terminals 11 shown in FIG. 1. Thus, the primary circuit 13 is electrically connected to the primary terminals 11.

In the present embodiment, the primary leads and the primary die pad 60 are formed from the same material. The primary leads and the primary die pad 60 may be formed integrally. The primary leads are arranged separately from the primary die pad 60 at a side of the primary die pad 60 opposite from the secondary die pad 70. The primary leads include portions projecting out from the encapsulation resin 80. The portions of the primary leads projecting out from the encapsulation resin 80 are used as external terminals of the signal transmission device 10.

The second electrode pads 32 of the first chip 30 are separately connected to the first electrode pads 51 of the insulation chip 50 by the wires W. Thus, the primary circuit 13 is electrically connected to the capacitors 15A and 15B (refer to FIG. 1). In other words, the primary signal lines 16A and 16B (refer to FIG. 1) include the interconnect layer 34 of the first chip 30, the second electrode pads 32, the wires W, and the first electrode pads 51.

The second electrode pads 52 of the insulation chip 50 are separately connected to the first electrode pads 41 of the second chip 40 by the wires W. Thus, the capacitors 15A and 15B are electrically connected to the secondary circuit 14. In other words, the secondary signal lines 17A and 17B (refer to FIG. 1) include the second electrode pads 52, the wires W, the first electrode pads 41 of the second chip 40, and the interconnect layer 44.

The second electrode pads 42 of the second chip 40 are separately connected by wires W to secondary leads, which are not shown. The secondary leads are parts forming the secondary terminals 12 shown in FIG. 1. Thus, the secondary circuit 14 is electrically connected to the secondary terminals 12.

In the present embodiment, the secondary leads and the secondary die pad 70 are formed from the same material. The secondary leads and the secondary die pad 70 may be formed integrally. Moreover, the primary leads, the primary die pad 60, the secondary leads, and the secondary die pad 70 may be formed integrally. The secondary leads are arranged separately from the secondary die pad 70 at a side of the secondary die pad 70 opposite from the primary die pad 60. The secondary leads include portions projecting out from the encapsulation resin 80. The portions of the secondary leads projecting out from the encapsulation resin 80 are used as external terminals of the signal transmission device 10.

### Detailed Structure of Insulation Chip

The structure of the insulation chip 50 will now be described in detail with reference to FIGS. 2 to 6. In the description hereafter, for the sake of convenience, the two first electrode pads 51 are referred to as a first electrode pad 51A and a first electrode pad 51B, and the two second electrode pads 52 are referred to as a second electrode pad 52A and the second electrode pad 52B.

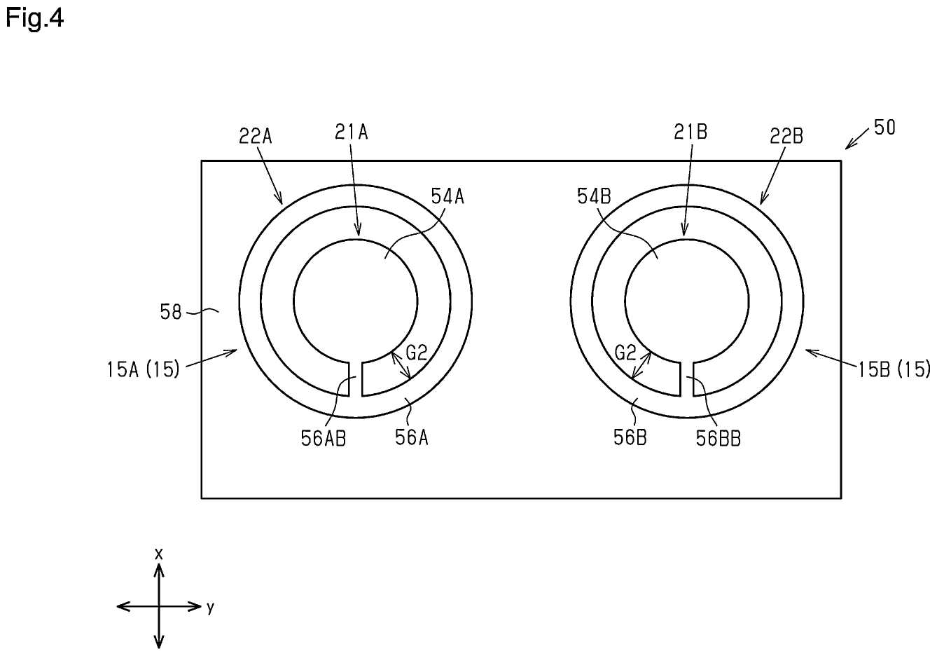

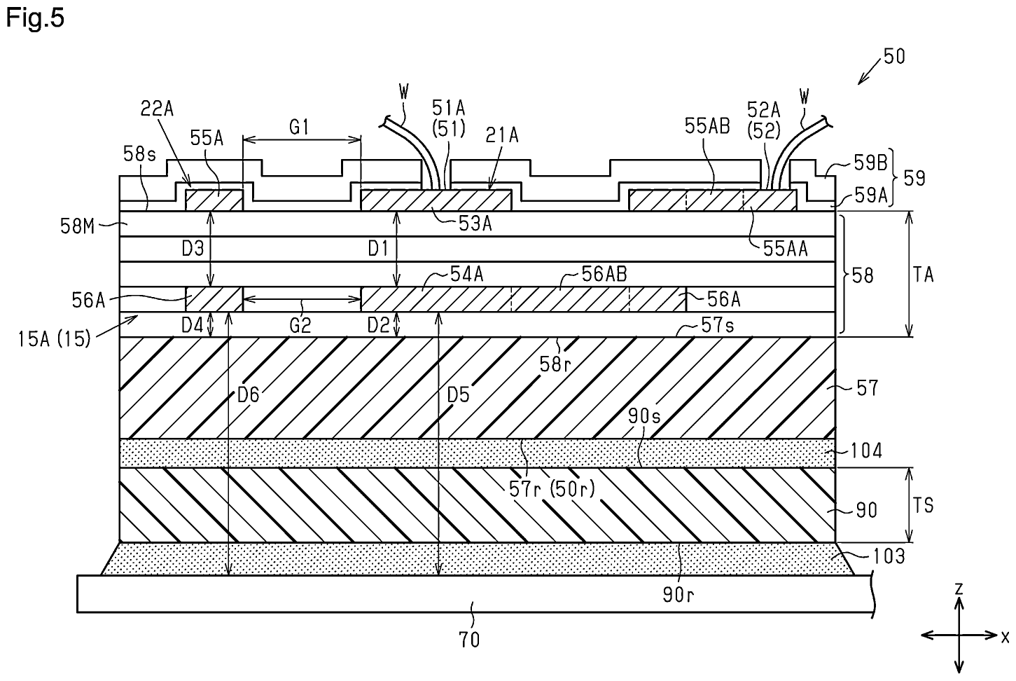

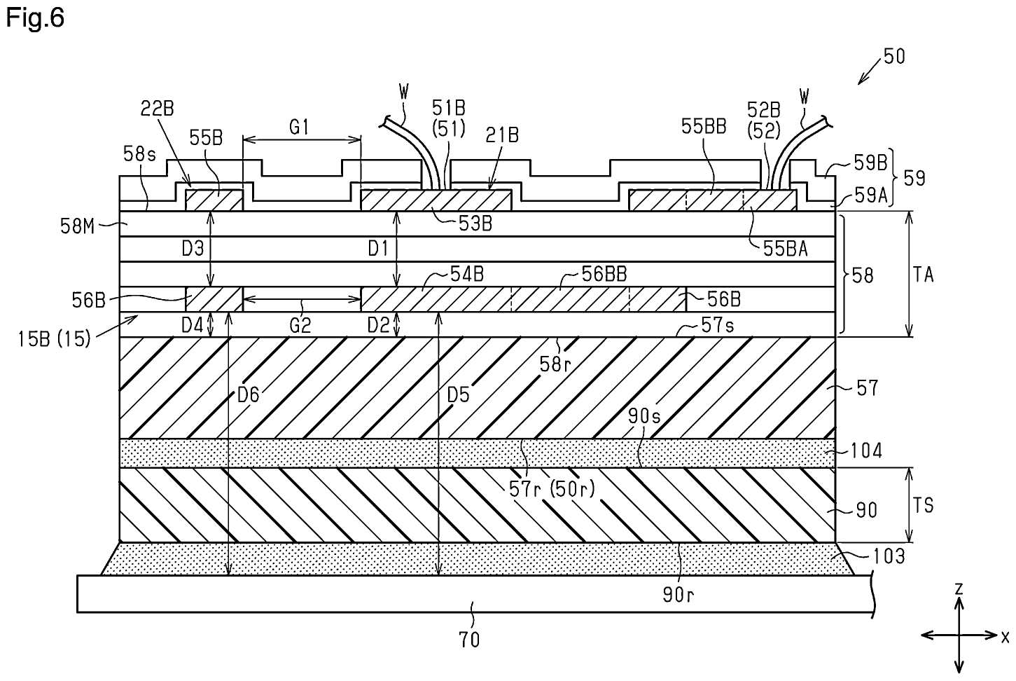

FIG. 3 is a schematic plan view showing the planar structure of the insulation chip 50. FIG. 4 is a schematic cross-sectional view showing the cross-sectional structure of the insulation chip 50 taken along a plane orthogonal to the thickness-wise direction of the insulation chip 50. FIGS. 5 and 6 are schematic cross-sectional views showing a cross-sectional structure taken along respective indicating lines shown in FIG. 3. FIGS. 4 to 6 do not show the hatching lines of some of the components for simplicity and clarity. In the following description, a direction from the chip back surface 50r toward the chip front surface 50s of the insulation chip 50 is referred to as an upward direction. A direction from the chip front surface 50s toward the chip back surface 50r is referred to as a downward direction.

As shown in FIG. 3, the insulation chip 50 is a single chip in which the two capacitors 15A and 15B are integrated. The insulation chip 50 is separate from the first chip 30 and the second chip 40 (refer to FIG. 2) and is dedicated to the two capacitors 15A and 15B.

The two capacitors 15A and 15B are separated from each other in the y-direction. In other words, as viewed in the z-direction, the two capacitors 15A and 15B are separated from each other in the longitudinal direction of the insulation chip 50.

As shown in FIGS. 2 to 4, in the capacitor 15A, the first capacitor 21A includes a first front electrode plate 53A and a first back electrode plate 54A opposed to each other in the z-direction. In the present embodiment, the first front electrode plate 53A and the first back electrode plate 54A are arranged to be concentric. The first front electrode plate 53A corresponds to the first electrode 23A (refer to FIG. 1) of the first capacitor 21A. The first back electrode plate 54A corresponds to the second electrode 24A (refer to FIG. 1) of the first capacitor 21A.

As shown in FIG. 3, as viewed in the z-direction, the first front electrode plate 53A is circular. As shown in FIG. 4, as viewed in the z-direction, the first back electrode plate 54A is circular. As shown in FIGS. 3 and 4, the first front electrode plate 53A is equal to the first back electrode plate 54A in area as viewed in the z-direction. When the difference in area as viewed in the z-direction between the first front electrode plate 53A and the first back electrode plate 54A is, for example, within 10% of the area of the first front electrode plate 53A as viewed in the z-direction, it is considered that the first front electrode plate 53A is equal to the first back electrode plate 54A in area as viewed in the z-direction.

As shown in FIGS. 2 to 4, in the capacitor 15A, the second capacitor 22A includes a second front electrode plate 55A and a second back electrode plate 56A opposed to each other in the z-direction. In the present embodiment, the second front electrode plate 55A and the second back electrode plate 56A are arranged to be concentric. The second front electrode plate 55A corresponds to the second electrode 26A (refer to FIG. 1) of the second capacitor 22A, and the second back electrode plate 56A corresponds to the first electrode 25A (refer to FIG. 1) of the second capacitor 22A.

As shown in FIG. 3, as viewed in the z-direction, the second front electrode plate 55A has a closed-annular shape. The second front electrode plate 55A has an inner diameter that is greater than a diameter of the first front electrode plate 53A. As shown in FIG. 4, as viewed in the z-direction, the second back electrode plate 56A has a closed-annular shape. The second back electrode plate 56A has an inner diameter that is greater than a diameter of the first back electrode plate 54A. As shown in FIGS. 3 and 4, the second front electrode plate 55A is equal to the second back electrode plate 56A in area as viewed in the z-direction. When the difference in area as viewed in the z-direction between the second front electrode plate 55A and the second back electrode plate 56A is, for example, within 10% of the area of the second front electrode plate 55A as viewed in the z-direction, it is considered that the second front electrode plate 55A is equal to the second back electrode plate 56A in area as viewed in the z-direction.

As shown in FIG. 3, as viewed in the z-direction, the second front electrode plate 55A is formed to surround the first front electrode plate 53A. The center of the second front electrode plate 55A coincides with the center of the first front electrode plate 53A. That is, the first front electrode plate 53A and the second front electrode plate 55A are arranged to be concentric. In other words, the first front electrode plate 53A and the second front electrode plate 55A are concentrically formed. The second front electrode plate 55A is aligned with the first front electrode plate 53A in the z-direction.

As viewed in the z-direction, the second front electrode plate 55A is spaced apart from the first front electrode plate 53A. As viewed in the z-direction, a distance G1 between the first front electrode plate 53A and the second front electrode plate 55A is constant along the entire circumference of the first front electrode plate 53A. The distance G1 is greater than or equal to a distance D1 (refer to FIG. 5) between the first front electrode plate 53A and the first back electrode plate 54A in the z-direction. Since the distance G1 is constant along the entire circumference of the first front electrode plate 53A, the distance G1 is the minimum distance between the first front electrode plate 53A and the second front electrode plate 55A in the z-direction. The distance D1 is also constant in the entire region of the first front electrode plate 53A opposed to the first back electrode plate 54A and in the entire region of the first back electrode plate 54A opposed to the first front electrode plate 53A. Hence, the distance D1 is the minimum distance between the first front electrode plate 53A and the first back electrode plate 54A. Thus, the minimum distance between the first front electrode plate 53A and the second front electrode plate 55A as viewed in the z-direction is greater than or equal to the minimum distance between the first front electrode plate 53A and the first back electrode plate 54A. In the present embodiment, the distance G1 is equal to the distance D1.

The second capacitor 22A includes an electrode pad 55AA electrically connected to the second front electrode plate 55A. As viewed in the z-direction, the electrode pad 55AA and the second front electrode plate 55A are located at different positions. As shown in FIG. 2, in the present embodiment, the electrode pad 55AA is arranged closer to the second chip 40 than the second front electrode plate 55A is. The electrode pad 55AA and the second front electrode plate 55A are connected by a connector 55AB. In the present embodiment, the second front electrode plate 55A, the electrode pad 55AA, and the connector 55AB are formed integrally. The second front electrode plate 55A, the electrode pad 55AA, and the connector 55AB are aligned with each other in the z-direction. Thus, the electrode pad 55AA corresponds to a “region located at a position differing from a position of the second front electrode plate and formed integrally with the second front electrode plate.”

As described above, the electrode pad 55AA is formed at a position separate from the second front electrode plate 55A in the x-direction. Thus, the first front electrode plate 53A and the second front electrode plate 55A are offset with respect to the insulation chip 50 in the x-direction. In the present embodiment, the first front electrode plate 53A and the second front electrode plate 55A are located toward the first chip 30 from the center of the insulation chip 50 in the x-direction. In the same manner, the first back electrode plate 54A and the second back electrode plate 56A are located toward the first chip 30 from the center of the insulation chip 50 in the x-direction.

As shown in FIG. 4, as viewed in the z-direction, the second back electrode plate 56A is formed to surround the first back electrode plate 54A. The center of the second back electrode plate 56A coincides with the center of the first back electrode plate 54A. In other words, the first back electrode plate 54A and the second back electrode plate 56A are concentrically formed. The second back electrode plate 56A is aligned with the first back electrode plate 54A in the z-direction.

As viewed in the z-direction, the second back electrode plate 56A is spaced apart from the first back electrode plate 54A. As viewed in the z-direction, a distance G2 between the first back electrode plate 54A and the second back electrode plate 56A is constant along the entire circumference of the first back electrode plate 54A. The distance G2 is greater than or equal to a distance D3 (refer to FIG. 5) between the second front electrode plate 55A and the second back electrode plate 56A in the z-direction. Since the distance G2 is constant along the entire circumference of the first back electrode plate 54A, the distance G2 is the minimum distance between the first back electrode plate 54A and the second back electrode plate 56A as viewed in the z-direction. The distance D3 is also constant in the entire region of the second front electrode plate 55A opposed to the second back electrode plate 56A and in the entire region of the second back electrode plate 56A opposed to the second front electrode plate 55A. Hence, the distance D3 is the minimum distance between the second front electrode plate 55A and the second back electrode plate 56A. Thus, the minimum distance between the first back electrode plate 54A and the second back electrode plate 56A as viewed in the z-direction is greater than or equal to the minimum distance between the second front electrode plate 55A and the second back electrode plate 56A. In the present embodiment, the distance G2 is equal to the distance D3. In the present embodiment, the distance D3 is equal to the distance D1. When the difference between the distance D3 and the distance D1 is, for example, within 10% of the distance D1, it is considered that the distance D3 is equal to the distance D1.

In the present embodiment, the second back electrode plate 56A is equal to the first back electrode plate 54A in area as viewed in the z-direction. When the difference in area as viewed in the z-direction between the second back electrode plate 56A and the first back electrode plate 54A is, for example, within 10% of the area of the first back electrode plate 54A as viewed in the z-direction, it is considered that the second back electrode plate 56A is equal to the first back electrode plate 54A in area as viewed in the z-direction.

As described above, the first front electrode plate 53A is equal in area to the second front electrode plate 55A. The first back electrode plate 54A is equal in area to the second back electrode plate 56A. The distance D1 is equal to the distance D3. Therefore, the first capacitor 21A is equal in capacitance to the second capacitor 22A.

The first back electrode plate 54A and the second back electrode plate 56A are connected by a joint interconnect 56AB. The joint interconnect 56AB is aligned with the back electrode plates 54A and 56A in the z-direction. In the present embodiment, the joint interconnect 56AB extends in the x-direction from an end of the first back electrode plate 54A located toward the second chip 40 (refer to FIG. 2). The joint interconnect 56AB may be located in any position in the circumferential direction of the first back electrode plate 54A as long as the joint interconnect 56AB connects the first back electrode plate 54A and the second back electrode plate 56A. In other words, the joint interconnect 56AB extends in a radial direction of the first back electrode plate 54A. Thus, the first back electrode plate 54A is electrically connected to the second back electrode plate 56A in an element insulation layer 58.

As shown in FIGS. 3, 4, and 6, in the capacitor 15B, the first capacitor 21B includes a first front electrode plate 53B and a first back electrode plate 54B opposed to each other in the z-direction. The second capacitor 22B includes a second front electrode plate 55B and a second back electrode plate 56B opposed to each other in the z-direction. In the same manner as the second capacitor 22A, the second capacitor 22B includes an electrode pad 55BA and a connector 55BB. The first back electrode plate 54B and the second back electrode plate 56B are connected by a joint interconnect 56BB. As shown in FIGS. 3, 4, and 6, the capacitor 15B has the same structure as the capacitor 15A and thus will not be described in detail.

In the present embodiment, the first front electrode plates 53A and 53B, the first back electrode plates 54A and 54B, the second front electrode plates 55A and 55B, and the second back electrode plates 56A and 56B are formed from a material including Al. Thus, the first electrode pads 51A and 51B and the second electrode pads 52A and 52B are formed from a material including Al. The material forming the electrode plates 53A, 53B, 54A, 54B, 55A, 55B, 56A, and 56B may be changed in any manner and may include, for example, Cu, W, or the like. The electrode plates 53A, 53B, 54A, 54B, 55A, 55B, 56A, and 56B may be formed from a material including at least one of Cu, Al, and W. Alternatively, the electrode plates 53A, 53B, 54A, 54B, 55A, 55B, 56A, and 56B may be formed from a material including Ti.

As shown in FIGS. 5 and 6, the insulation chip 50 includes a substrate 57 and the element insulation layer 58 formed on the substrate 57.

The substrate 57 is formed of, for example, a semiconductor substrate. In the present embodiment, the substrate 57 includes a semiconductor substrate formed from a material including Si. As the semiconductor substrate, a wide-bandgap semiconductor or a compound semiconductor may be used for the substrate 57. The substrate 57 may be an insulating substrate formed from a material including glass or an insulating substrate formed from a material including ceramics such as alumina instead of a semiconductor substrate.

The wide-bandgap semiconductor is a semiconductor substrate having a band gap that is greater than or equal to 2.0 eV. The wide-bandgap semiconductor may be silicon carbide (SiC). The compound semiconductor may be a group III-V compound semiconductor. The compound semiconductor may include at least one of aluminum nitride (AlN), indium nitride (InN), gallium nitride (GaN), and gallium arsenide (GaAs).

The substrate 57 includes a substrate front surface 57s and a substrate back surface 57r facing opposite directions in the z-direction. Insulation films 58M are stacked on the substrate front surface 57s in the z-direction. In the present embodiment, the element insulation layer 58 includes the insulation films 58M stacked on one another. Thus, the z-direction is a thickness-wise direction of the element insulation layer 58. The phase “viewed in the z-direction” includes the meaning of “viewed in the thickness-wise direction of the element insulation layer 58.”

Each of the insulation films 58M is, for example, an interlayer insulation film and is an oxide film formed from a material including silicon oxide (SiO₂). The thickness of the insulation film 58M may be, for example, in a range of 500 nm to 5000 nm. In the present embodiment, the thickness of the insulation film 58M is, for example, approximately 2000 nm.

The element insulation layer 58 includes a front surface 58s and a back surface 58r. The front surface 58s faces the same direction as the substrate front surface 57s of the substrate 57 face in the same direction. The back surface 58r faces the same direction as the substrate back surface 57r of the substrate 57. The front surface 58s of the element insulation layer 58 is the front surface of the uppermost the insulation film 58M among the insulation films 58M stacked in the z-direction. The back surface 58r of the element insulation layer 58 is the back surface of the lowermost insulation film 58M among the insulation films 58M stacked in the z-direction. The back surface 58r of the element insulation layer 58 is opposed to the substrate front surface 57s of the substrate 57. More specifically, the back surface 58r of the element insulation layer 58 is in contact with the substrate front surface 57s of the substrate 57.

As shown in FIGS. 5 and 6, the first front electrode plates 53A and 53B and the second front electrode plates 55A and 55B are arranged on the front surface 58s of the element insulation layer 58. In other words, the first front electrode plates 53A and 53B and the second front electrode plates 55A and 55B are arranged on the element insulation layer 58.

The insulation chip 50 includes a front protective layer 59 formed on the front surface 58s of the element insulation layer 58. The front protective layer 59 includes the chip front surface 50s of the insulation chip 50 and protects the element insulation layer 58. The front protective layer 59 includes a protective film 59A and a passivation film 59B formed on the protective film 59A. The protective film 59A is formed from, for example, a material including SiO₂. The passivation film 59B is formed from, for example, a material including SiN. The passivation film 59B includes the chip front surface 50s of the insulation chip 50.

The front protective layer 59 covers the front surface 58s of the element insulation layer 58 and the second front electrode plates 55A and 55B. The front protective layer 59 covers the first front electrode plate 53A so that the surface of the first front electrode plate 53A is partially exposed. The electrode pads 55AA and 55BA are exposed without being covered by the front protective layer 59. The connectors 55AB and 55BB are covered by the front protective layer 59. More specifically, the first front electrode plates 53A and 53B and the second front electrode plates 55A and 55B are covered by the protective film 59A and the passivation film 59B. The protective film 59A and the passivation film 59B include four openings that expose the electrode pads 55AA and 55BA and portions of the surfaces of the first front electrode plates 53A and 53B. The four openings include a first opening that exposes a central region of the first front electrode plate 53A, a second opening that exposes a central region of the first front electrode plate 53B, a third opening that exposes the electrode pad 55AA, and a fourth opening that exposes the electrode pad 55BA. Thus, the first front electrode plates 53A and 53B and the electrode pads 55AA and 55BA each include an exposed surface for connection with the wire W through the opening. The exposed surfaces of the first front electrode plates 53A and 53B include the first electrode pads 51A and 51B. The electrode pads 55AA and 55BA include the second electrode pads 52A and 52B. The region excluding the central region of the first front electrode plates 53A and 53B is covered by the protective film 59A and the passivation film 59B. The second front electrode plates 55A and 55B and the connectors 55AB and 55BB are covered by the protective film 59A and the passivation film 59B.

As shown in FIGS. 5 to 6, the first back electrode plates 54A and 54B and the second back electrode plates 56A and 56B are arranged in the element insulation layer 58.

As shown in FIG. 5, the first back electrode plate 54A is embedded in the element insulation layer 58. More specifically, the first back electrode plate 54A extends through one of the insulation films 58M in the z-direction. The first back electrode plate 54A is formed by, for example, filling the opening with a conductive member that is formed from a material including Al.

One or more insulation films 58M are arranged between the first front electrode plate 53A and the first back electrode plate 54A in the z-direction. That is, the element insulation layer 58 includes a portion (inter-electrode insulation film) located between the first front electrode plate 53A and the first back electrode plate 54A in the z-direction. In other words, the first front electrode plate 53A and the first back electrode plate 54A are opposed to each other via the portion (inter-electrode insulation film) of the element insulation layer 58.

One or more insulation films 58M are arranged between the first back electrode plate 54A and the substrate 57 in the z-direction. Thus, the first back electrode plate 54A is insulated from the substrate 57 by the element insulation layer 58. As described above, the element insulation layer 58 is further arranged between the first back electrode plate 54A and the substrate 57.

The distance D1 between the first front electrode plate 53A and the first back electrode plate 54A in the z-direction is greater than a distance D2 between the first back electrode plate 54A and the back surface 58r of the element insulation layer 58 in the z-direction. Thus, while increases in thickness TA of the element insulation layer 58 are limited, the distance D1 is increased.

The second back electrode plate 56A is embedded in the element insulation layer 58. In the same manner as the first back electrode plate 54A, the second back electrode plate 56A is formed by filling the opening in one of the insulation films 58M with a conductive member. In the present embodiment, the first back electrode plate 54A, the second back electrode plate 56A, and the joint interconnect 56AB are formed integrally. More specifically, in the element insulation layer 58, one of the insulation films 58M includes openings corresponding to the first back electrode plate 54A, the second back electrode plate 56A, and the joint interconnect 56AB. When the openings are filled with the conductive member (Al), the first back electrode plate 54A, the second back electrode plate 56A, and the joint interconnect 56AB are formed integrally.

One or more of the insulation films 58M are arranged between the second front electrode plate 55A and the second back electrode plate 56A in the z-direction. That is, the element insulation layer 58 includes a portion (inter-electrode insulation film) located between the second front electrode plate 55A and the second back electrode plate 56A in the z-direction. In other words, the second front electrode plate 55A and the second back electrode plate 56A are opposed to each other via the portion (inter-electrode insulation film) of the element insulation layer 58.

One or more insulation films 58M are arranged between the second back electrode plate 56A and the substrate 57 in the z-direction. Thus, the second back electrode plate 56A is insulated from the substrate 57 by the element insulation layer 58. As described above, the element insulation layer 58 is further arranged between the second back electrode plate 56A and the substrate 57.

The distance D3 between the second front electrode plate 55A and the second back electrode plate 56A in the z-direction is greater than a distance D4 between the second back electrode plate 56A and the back surface 58r of the element insulation layer 58 in the z-direction. Thus, while increases in thickness TA of the element insulation layer 58 are limited, the distance D3 is increased. In the present embodiment, the distance D3 is equal to the distance D1. The distance D4 is equal to the distance D2.

The distance DI between the first front electrode plate 53A and the first back electrode plate 54A in the z-direction and the distance D3 between the second front electrode plate 55A and the second back electrode plate 56A in the z-direction may be changed in any manner in accordance with an insulation voltage necessary for the capacitor 15A. The insulation voltage necessary for the capacitor 15A depends on the distances D1 and D3. A distance between electrodes corresponding to the insulation voltage necessary for the capacitor 15A is referred to as a reference distance. In the present embodiment, the ratio of the sum of the distance D1 and the distance D3 to the reference distance is, for example, in a range of 1.0 to 2.0. The ratio is, for example, preferably 1.6. The sum of the distance D1 and the distance D3 is set to be greater than the reference distance taking into consideration a safety margin. An increase in the sum of the distance D1 and the distance D3 decreases the capacitance of the capacitor 15A. In addition, an increase in the sum of the distance D1 and the distance D3 may increase effects on the first front electrode plate 53A, the first back electrode plate 54A, the second front electrode plate 55A, or the second back electrode plate 56A received from other conductive members in the insulation chip 50. When such effects are considered, the insulation chip 50 will be enlarged. Therefore, it is preferred that the sum of the distance D1 and the distance D3 be set to be close to the reference distance in order to minimize decreases in the capacitance of the capacitor 15A and enlargement of the insulation chip 50.

As shown in FIGS. 5 and 6, the structure of the first front electrode plate 53B, the first back electrode plate 54B, the second front electrode plate 55B, and the second back electrode plate 56B of the capacitor 15B in the element insulation layer 58 is the same as that of the electrode plates 53A, 54A, 55A, and 56A of the capacitor 15A and thus will not be described in detail.

As shown in FIGS. 5 and 6, the insulation chip 50 is mounted on the secondary die pad 70. More specifically, the insulation chip 50 is mounted on the secondary die pad 70 via an insulating substrate 90. In other words, the insulating substrate 90 is located between the insulation chip 50 and the secondary die pad 70. The insulating substrate 90 is bonded to the secondary die pad 70 by a third bonding material 103. The insulation chip 50 is bonded to the insulating substrate 90 by a fourth bonding material 104. The third bonding material 103 and the fourth bonding material 104 each are, for example, an insulative bonding material. The insulating substrate 90 corresponds to an “insulation member.” The third bonding material 103 corresponds to a “first insulative bonding material.” The fourth bonding material 104 corresponds to a “second insulative bonding material.”

The insulating substrate 90 is formed by an insulating substrate including alumina or an insulating substrate including glass. The insulating substrate 90 may be formed from a resin material. The insulating substrate 90 includes a front surface 90s and a back surface 90r facing opposite directions in the z-direction. The front surface 90s is in contact with the fourth bonding material 104. The back surface 90r is in contact with the third bonding material 103.

The insulating substrate 90 has a thickness TS that is greater than the distance D2 between the first back electrode plate 54A and the back surface 58r of the element insulation layer 58. The thickness TS of the insulating substrate 90 is defined as a distance between the front surface 90s and the back surface 90r of the insulating substrate 90 in the z-direction.

As described above, the insulation chip 50 is mounted on the secondary die pad 70 via the insulating substrate 90. Thus, a distance D5 between the first back electrode plate 54A (54B) of the capacitor 15A (15B) and the secondary die pad 70 is greater than or equal to the distance D1. The distance D5 is greater than or equal to the thickness TA of the element insulation layer 58. In the present embodiment, the distance D5 is greater than the thickness TA of the element insulation layer 58. A distance D6 between the second back electrode plate 56A (56B) of the capacitor 15A (15B) and the secondary die pad 70 is greater than the distance D3. The distance D6 is equal to the distance D5.

The thickness TS of the insulating substrate 90 and the distances D5 and D6 may be changed in any manner. The thickness TS of the insulating substrate 90 may be, for example, less than or equal to the distance D2 (D4) or greater than or equal to the distance D1 (D3). The distances D5 and D6 may be less than or equal to the distance D1 (D3) or less than the thickness TA of the element insulation layer 58.

As shown in FIG. 2, the insulation chip 50 is mounted on the secondary die pad 70 via the insulating substrate 90. Thus, the distance between the secondary die pad 70 and the substrate 57 of the insulation chip 50 in the z-direction is greater than the distance between the secondary die pad 70 and the second substrate 43 of the second chip 40 in the z-direction. Also, the distance between the secondary die pad 70 and the substrate 57 of the insulation chip 50 in the z-direction is greater than the distance between the primary die pad 60 and the first substrate 33 of the first chip 30 in the z-direction.

### Method for Manufacturing Insulation Chip and Signal Transmission Device

An example of a method for manufacturing the insulation chip 50 of the present embodiment and an example of a method for manufacturing the signal transmission device 10 will now be described briefly. A case in which multiple insulation chips 50 are simultaneously forming will be described below.

The method for manufacturing the insulation chip 50 includes a wafer preparing step, a first insulation layer and capacitor forming step, a second insulation layer forming step, and a singulation step.

In the wafer preparing step, a semiconductor wafer that forms the substrate 57 is prepared. The semiconductor wafer is formed from, for example, a material including Si. The semiconductor wafer has a size such that multiple insulation chips 50 are formed.

In the first insulation layer and capacitor forming step, an element insulation layer is formed on the semiconductor wafer. More specifically, insulation films formed from a material including SiO₂ are stacked to form the element insulation layer. The insulation films form the insulation films 58M (refer to FIG. 5). The element insulation layer is formed, for example, on the entirety of a front surface of the semiconductor wafer. The element insulation layer is an insulation layer that forms the element insulation layer 58 (refer to FIG. 5).

Openings corresponding to the first back electrode plate 54A (54B) and the second back electrode plate 56A (56B) are formed in an insulation film in which the first back electrode plate 54A (54B) and the second back electrode plate 56A (56B) will be formed. The openings are filled with a conductive material to form the first back electrode plate 54A (54B) and the second back electrode plate 56A (56B). The conductive material includes, for example, Al.

Then, the first front electrode plate 53A (53B) and the second front electrode plate 55A (55B) are formed on a surface of the element insulation layer. The first front electrode plate 53A (53B) and the second front electrode plate 55A (55B) are formed from a material including, for example, Al. The material forming the electrode plates 53A (53B), 54A (54B), 55A (55B), and 56A (56B) may be other conductive materials such as W, Ti, Cu, or the like.

In the second insulation layer forming step, a protective film is formed. The protective film is an insulation film that forms the protective film 59A (refer to FIG. 5) and is formed on the entirety of a front surface of the element insulation layer. The protective film is formed from, for example, a material including SiO₂. Then, a passivation film is formed. The passivation film is an oxide film that forms the passivation film 59B (refer to FIG. 5) and is formed on the entirety of a front surface of the protection film. The passivation film is formed from, for example, a material including SiN. Openings that expose a portion including the center of the first front electrode plate 53A (53B) and the electrode pad 55AA (55BA) of the second front electrode plate 55A (55B) are formed in the protective film and the passivation film. As a result, the portion of the first front electrode plate 53A (53B) exposed from the protective film and the passivation film forms the first electrode pad 51A (51B). The electrode pad 55AA (55BA) forms the second electrode pad 52A (52B).

Alternatively, in forming the protective film and the passivation film, for example, a mask may be used to form the openings that expose the portion including the center of the first front electrode plate 53A (53B) and the electrode pad 55AA (55BA) of the second front electrode plate 55A (55B).

In the singulation step, the semiconductor wafer on which the element insulation layer is formed is cut to have the size of the insulation chip 50. As a result, the insulation chip 50 is singulated. The steps described above manufactures the insulation chip 50.

The method for manufacturing the signal transmission device 10 includes a frame preparing step, a chip mounting step, a wire forming step, a resin layer forming step, a separating step, and a terminal forming step.

In the frame preparing step, a frame that forms the primary leads, the secondary leads, the primary die pad 60, and the secondary die pad 70 (refer to FIG. 2) is prepared. In an example, the frame is a single plate formed from a material including Cu. Pressing or etching is performed on the frame to form the primary leads, the secondary leads, the primary die pad 60, and the secondary die pad 70. In this step, the primary leads, the secondary leads, the primary die pad 60, and the secondary die pad 70 are connected to the frame.

In the chip mounting step, the first chip 30 is mounted on the primary die pad 60 by die bonding, and the second chip 40 and the insulation chip 50 are mounted on the secondary die pad 70 by die bonding.

More specifically, the first bonding material 101 is applied to a portion of the primary die pad 60 on which the first chip 30 will be mounted. The second bonding material 102 is applied to a portion of the second chip 40 on which the secondary die pad 70 will be mounted. The first bonding material 101 and the second bonding material 102 are a conductive bonding material. The first chip 30 is mounted on the first bonding material 101. The second chip 40 is mounted on the second bonding material 102. The first bonding material 101 and the second bonding material 102 are solidified. In an example, when the bonding materials 101 and 102 include solder paste, the bonding materials 101 and 102 are cooled so that the bonding materials 101 and 102 are solidified. Then, the third bonding material 103 is applied to a portion of the secondary die pad 70 on which the insulation chip 50 will be mounted. The third bonding material 103 is an insulative bonding material. The insulating substrate 90 is mounted on the third bonding material 103. The fourth bonding material 104 is applied to the insulating substrate 90. The fourth bonding material 104 is an insulative bonding material. The insulation chip 50 is mounted on the fourth bonding material 104. The bonding materials 103 and 104 are solidified. In an example, when the bonding materials 103 and 104 are formed from a material including an epoxy resin, the epoxy resin is mixed with a curing agent so that the bonding materials 103 and 104 are solidified.

In the wire forming step, a wire W that connects each of the chips 30, 40, and 50, wires W that connect the first chip 30 to the primary leads, and wires W that connect the second chip 40 to the secondary leads. The wires W are formed by, for example, a wire bonder.

In the resin layer forming step, a resin layer is formed to encapsulate the chips 30, 40, and 50, the wires W, and the die pads 60 and 70. The resin layer is configured to form the encapsulation resin 80 and is formed from, for example, a black epoxy resin. The resin layer is formed by, for example, transfer molding or compression molding. The primary leads and the secondary leads partially project from the resin layer.

In the separating step, the resin layer is cut, and the primary leads, the secondary leads, the primary die pad 60, and the secondary die pad 70 are separated from the frame. In this step, for example, a dicing blade is used to cut the resin layer and the frame. In this step, the primary leads and the secondary leads are cut from the frame so that the primary leads and the secondary leads include portions projecting from the resin layer.

In the terminal forming step, the portions of the primary leads and the secondary leads projecting from the resin layer are bent into a predetermined shape by a bending process. The steps described above manufacture the signal transmission device 10.

### Operation

The operation of the present embodiment will now be described.

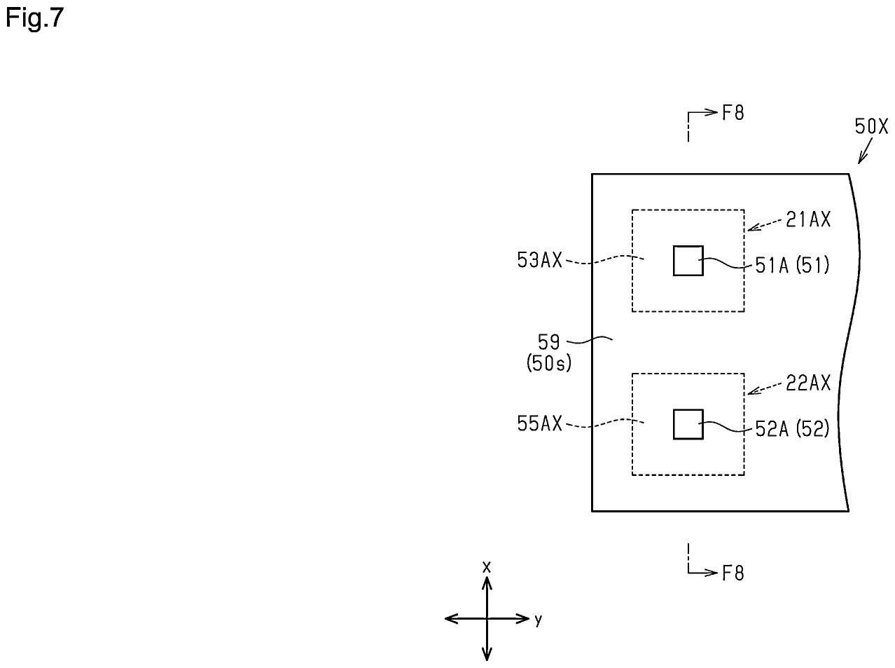

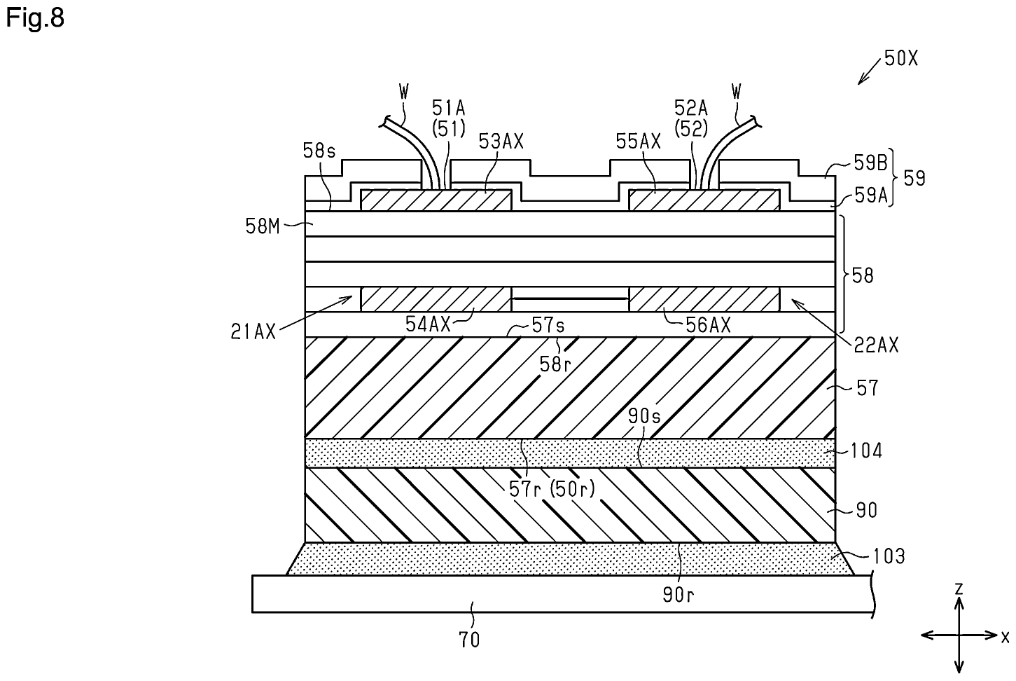

FIG. 7 is a schematic diagram showing a planar structure of a portion of an insulation chip 50X in a comparative example. FIG. 8 is a schematic diagram showing a cross-sectional structure of the insulation chip 50X in the comparative example. FIG. 8 is a schematic diagram showing a cross-sectional structure of a first capacitor 21AX and a second capacitor 22AX. The insulation chip 50X of the comparative example differs from the insulation chip 50 of the embodiment in only the structure of capacitors. Thus, the same reference characters are given to those components that are the same as the corresponding components of the embodiment. Such components will not be described in detail.

As shown in FIG. 7, the insulation chip 50X has a package structure in which the first capacitor 21AX and the second capacitor 22AX are integrated in a single chip.

As shown in FIG. 8, the first capacitor 21AX includes a first front electrode plate 53AX and a first back electrode plate 54AX. The second capacitor 22AX includes a second front electrode plate 55AX and a second back electrode plate 56AX.

The first front electrode plate 53AX and the first back electrode plate 54AX are opposed to each other in the z-direction. The second front electrode plate 55AX and the second back electrode plate 56AX are opposed to each other in the z-direction. The first front electrode plate 53AX and the second front electrode plate 55AX are separated from each other in the x-direction. The first back electrode plate 54AX and the second back electrode plate 56AX are separated from each other in the x-direction. The first back electrode plate 54AX and the second back electrode plate 56AX are electrically connected to the element insulation layer 58.

As shown in FIG. 7, as viewed in the z-direction, the electrode plates 53AX, 54AX, 55AX, and 56AX are each rectangular. In this structure, an electric field tends to concentrate on corners of the electrode plates 53AX, 54AX, 55AX, and 56AX. The electric field concentration on corners of the electrode plates 53AX, 54AX, 55AX, and 56AX may decrease the insulation voltage of the capacitors 21AX and 22AX.

In this regard, in the present embodiment, as viewed in the z-direction, the first front electrode plate 53A (53B) and the first back electrode plate 54A (54B) are circular. Each of the second front electrode plate 55A (55B) and the second back electrode plate 56A (56B) is annular and has an inner diameter that is greater than the diameter of the first front electrode plate 53A (53B) and the first back electrode plate 54A (54B). The second front electrode plate 55A is formed to surround the first front electrode plate 53A and to be concentric with the first front electrode plate 53A. The second back electrode plate 56A is formed to surround the first back electrode plate 54A and to be concentric with the first back electrode plate 54A. Thus, as viewed in the z-direction, the electrode plates 53A (53B), 54A (54B), 55A (55B), and 56A (56B) do not include a corner on which an electric field concentrates. In addition, the distance G1 between the first front electrode plate 53A (53B) and the second front electrode plate 55A (55B) is constant. The distance G2 between the first back electrode plate 54A (54B) and the second back electrode plate 56A (56B) is constant. Thus, an electric field is less likely to concentrate. As a result, the insulation voltage of the insulation chip 50 is less likely to be decreased.

### Advantages

The present embodiment has the following advantages.

(1) The insulation chip 50 includes the element insulation layer 58 including the front surface 58s and the back surface 58r, and the first capacitor 21A (21B) and the second capacitor 22A (22B) formed on the element insulation layer 58. The first capacitor 21A (21B) includes the first front electrode plate 53A (53B) and the first back electrode plate 54A (54B) opposed to each other in the z-direction, that is, the thickness-wise direction of the element insulation layer 58. The second capacitor 22A (22B) includes the second front electrode plate 55A (55B) surrounding the first front electrode plate 53A (53B) as viewed in the z-direction and the second back electrode plate 56A (56B) surrounding the first back electrode plate 54A (54B) as viewed in the z-direction. The second front electrode plate 55A (55B) and the second back electrode plate 56A (56B) are opposed to each other in the z-direction. The first back electrode plate 54A (54B) and the second back electrode plate 56A (56B) are electrically connected in the element insulation layer 58.

In a typical insulation ship including a single capacitor, the breakdown voltage of the insulation chip is improved by increasing the distance between the front electrode plate and the back electrode plate in the z-direction. However, as the distance between the front electrode plate and the back electrode plate is increased in the z-direction, the thickness of the element insulation layer is increased. When the thickness of the element insulation layer is increased, warping of the semiconductor wafer is increased during the manufacturing of the insulation chip. This interferes with the manufacturing of the insulation chip.

In this regard, in the present embodiment, the first capacitor 21A (21B) and the second capacitor 22A (22B) are connected in series, and the second capacitor 22A (22B) and the first capacitor 21A (21B) are arranged in a direction orthogonal to the z-direction. Thus, without increasing the thickness TA of the element insulation layer 58, the insulation voltage of the insulation chip 50 is improved. This achieves improvement of the insulation voltage of the insulation chip 50 while facilitating the manufacturing of the insulation chip 50.

In addition, as viewed in the z-direction, the second front electrode plate 55A (55B) is formed to surround the first front electrode plate 53A (53B). As viewed in the z-direction, the second back electrode plate 56A (56B) is formed to surround the first back electrode plate 54A (54B). As compared to the structure of the insulation chip 50X in the comparative example shown in FIG. 7, the front electrode plates 53A (53B) and 55A (55B) and the back electrode plates 54A (54B) and 56A (56B) are formed in a smaller space in the x-direction. Thus, the insulation chip 50 is reduced in size in the x-direction.

(2) As viewed in the z-direction, the first front electrode plate 53A (53B) is circular. The second front electrode plate 55A (55B) is annular and has an inner diameter that is greater than the diameter of the first front electrode plate 53A (53B). The first front electrode plate 53A (53B) and the second front electrode plate 55A (55B) are arranged to be concentric. As viewed in the z-direction, the first back electrode plate 54A (54B) is circular. The second back electrode plate 56A (56B) is annular and has an inner diameter that is greater than the diameter of the first back electrode plate 54A (54B). The first back electrode plate 54A (54B) and the second back electrode plate 56A (56B) are arranged to be concentric.

In this structure, the distance G1 between the first front electrode plate 53A (53B) and the second front electrode plate 55A (55B) is constant in the circumferential direction of the first front electrode plate 53A (53B). The distance G2 between the first back electrode plate 54A (54B) and the second back electrode plate 56A (56B) is constant in the circumferential direction of the first back electrode plate 54A (54B). Thus, an electric field is less likely to concentrate between the first front electrode plate 53A (53B) and the second front electrode plate 55A (55B) and between the first back electrode plate 54A (54B) and the second back electrode plate 56A (56B). This avoids a decrease in the insulation voltage of the first capacitor 21A (21B) and the second capacitor 22A (22B). As a result, the insulation voltage of the insulation chip 50 is less likely to be decreased.

(3) The distance G1, which is the minimum distance between the first front electrode plate 53A (53B) and the second front electrode plate 55A (55B), is greater than or equal to the distance D1, which is the minimum distance between the first front electrode plate 53A (53B) and the first back electrode plate 54A (54B).

In this structure, the insulation voltage between the first front electrode plate 53A (53B) and the second front electrode plate 55A (55B) is greater than or equal to the insulation voltage between the first front electrode plate 53A (53B) and the first back electrode plate 54A (54B). Thus, the insulation voltage of the insulation chip 50 is less likely to be decreased.

(4) The insulation chip 50 includes the front protective layer 59 covering the front surface 58s of the element insulation layer 58, the first front electrode plate 53A (53B), and the second front electrode plate 55A (55B). The front protective layer 59 exposes a portion of the first front electrode plate 53A (53B).

In this structure, the exposed surface of the first front electrode plate 53A (53B), which is exposed from the front protective layer 59, is used as the first electrode pad 51A (51B). This eliminates the need for forming an electrode pad that differs from the first front electrode plate 53A (53B). For example, when an electrode pad is formed above the first front electrode plate 53A (53B) in the z-direction, one or more the insulation films 58M need to be arranged between the first front electrode plate 53A and the electrode pad. This results in an increase in the thickness TA of the element insulation layer 58. In this regard, in the present embodiment, the first front electrode plate 53A (53B) includes the electrode pad. This limits the increase in the thickness TA of the element insulation layer 58. In addition, for example, when an electrode pad is separated from the first front electrode plate 53A (53B) in a direction orthogonal to the z-direction, a conductive path is formed between the first front electrode plate 53A (53B) and the electrode pad. The conductive path causes inductance to be formed. In this regard, in the present embodiment, the conductive path is not formed. This avoids occurrence of inductance caused by the conductive path.

(5) The signal transmission device 10 includes the first chip 30 including the primary circuit 13, the insulation chip 50, and the second chip 40 including the secondary circuit 14 configured to receive a signal from the primary circuit 13 through the insulation chip 50. The insulation chip 50 includes the element insulation layer 58 including the front surface 58s and the back surface 58r, and the first capacitor 21A (21B) and the second capacitor 22A (22B) formed on the element insulation layer 58. The first capacitor 21A (21B) includes the first front electrode plate 53A (53B) and the first back electrode plate 54A (54B) opposed to each other in the z-direction, that is, the thickness-wise direction of the element insulation layer 58. The second capacitor 22A (22B) includes the second front electrode plate 55A (55B) surrounding the first front electrode plate 53A (53B) as viewed in the z-direction and the second back electrode plate 56A (56B) surrounding the first back electrode plate 54A (54B) as viewed in the z-direction. The second front electrode plate 55A (55B) and the second back electrode plate 56A (56B) are opposed to each other in the z-direction. The first back electrode plate 54A (54B) and the second back electrode plate 56A (56B) are electrically connected in the element insulation layer 58.

This structure obtains the same advantage as the advantage (1) described above. As described above, the insulation voltage of the insulation chip 50 is improved. Accordingly, the insulation voltage of the signal transmission device 10 is improved.

(6) The insulating substrate 90 is arranged between the insulation chip 50 and the secondary die pad 70.

In this structure, the distances D5 and D6 between the first back electrode plate 54A (54B) and the secondary die pad 70 and between the second back electrode plate 56A (56B) and the secondary die pad 70 in the z-direction are increased. Thus, the insulation voltage between the first back electrode plate 54A (54B) and the secondary die pad 70 and the insulation voltage between the second back electrode plate 56A (56B) and the secondary die pad 70 are improved.

(7) The insulating substrate 90 is bonded to the secondary die pad 70 by the third bonding material 103. The third bonding material 103 includes an insulative bonding material.

In this structure, the insulation voltage between the first capacitor 21A (21B) and the secondary die pad 70 and the insulation voltage between the second capacitor 22A (22B) and the secondary die pad 70 are improved.

(8) The insulating substrate 90 is formed by an insulating substrate including alumina or an insulating substrate including glass.

In this structure, the insulating substrate 90 having a large thickness is readily formed as compared to a structure in which the insulating substrate 90 is formed of an insulation film.

### Modified Examples

The embodiment described above may be modified as follows. The embodiment and the following modified examples can be combined as long as the combined modifications remain technically consistent with each other.

The structure of the substrate 57 may be changed in any manner. In an example, a silicon-on-insulator (SOI) substrate may be used as the substrate 57.

One of the protective film 59A and the passivation film 59B may be omitted from the front protective layer 59. The front protective layer 59 may be omitted.

The third bonding material 103 may be formed from a conductive bonding material instead of an insulative bonding material.

The encapsulation resin 80 may be omitted from the signal transmission device 10.

The thickness of each of the front electrode plates 53A, 53B, 55A, and 55B and the thickness of each of the back electrode plates 54A, 54B, 56A, and 56B may be changed in any manner. In an example, the front electrode plates 53A, 53B, 55A, and 55B may be thicker than the back electrode plates 54A, 54B, 56A, and 56B.

The second front electrode plates 55A and 55B may be formed separately from the second electrode pads 52A and 52B. More specifically, the insulation chip 50 may include the second electrode pads 52A and 52B electrically connected to the second front electrode plates 55A and 55B. In this case, as viewed in the z-direction, the second electrode pads 52A and 52B are formed at a position separate from the second front electrode plates 55A and 55B. The front protective layer 59 exposes the surfaces of the second electrode pads 52A and 52B. The second front electrode plates 55A and 55B may be connected to the second electrode pads 52A and 52B by, for example, wires. In this case, the second electrode pads 52A and 52B may be formed from a material that differs from that of the second front electrode plates 55A and 55B.

In the embodiment described above, the first front electrode plates 53A and 53B and the second front electrode plates 55A and 55B are formed on the front surface 58s of the element insulation layer 58. However, there is no limit to this structure. In an example, the first front electrode plates 53A and 53B may be embedded in the element insulation layer 58. In this case, the first electrode pads 51A and 51B are arranged separately from the first front electrode plates 53A and 53B on the front surface 58s of the element insulation layer 58, which is located above the first front electrode plates 53A and 53B. The first front electrode plate 53A and the first electrode pad 51A are connected by a connection via. The first front electrode plate 53B and the first electrode pad 51B are connected by a connection via. In an example, the second front electrode plates 55A and 55B may be embedded in the element insulation layer 58. In this case, the second electrode pads 52A and 52B are arranged separately from the second front electrode plates 55A and 55B on the front surface 58s of the element insulation layer 58, which is located above the second front electrode plates 55A and 55B. The second front electrode plate 55A and the second electrode pad 52A are connected by a connection via. The second front electrode plate 55B and the second electrode pad 52B are connected by a connection via. In this case, the first electrode pads 51A and 51B and the second electrode pads 52A and 52B are formed from a material including Al in the same manner as the first front electrode plates 53A and 53B and the second front electrode plates 55A and 55B. The material forming the first electrode pads 51A and 51B and the second electrode pads 52A and 52B may be changed in any manner. In an example, the first electrode pads 51A and 51B may be formed from a material that differs from that of the first front electrode plates 53A and 53B. The second electrode pads 52A and 52B may be formed from a material that differs from that of the second front electrode plates 55A and 55B.

In the embodiment described above, the first front electrode plate 53A is equal in area to the second front electrode plate 55A. The first back electrode plate 54A is equal in area to the second back electrode plate 56A. However, there is no limit to this structure. The first front electrode plate 53A may be greater in area than the second front electrode plate 55A. The first back electrode plate 54A may be greater in area than the second back electrode plate 56A. In other words, the first capacitor 21A may be greater in capacitance than the second capacitor 22A. The second front electrode plate 55A may be greater in area than the first front electrode plate 53A. The second back electrode plate 56A may be greater in area than the first back electrode plate 54A. In other words, the second capacitor 22A may be greater in capacitance than the first capacitor 21A. The first front electrode plate 53B, the first back electrode plate 54B, the second front electrode plate 55B, and the second back electrode plate 56B may be changed in the same manner.

The insulation chip 50 may be mounted on the primary die pad 60 instead of the secondary die pad 70. In this case, the first chip 30 and the insulation chip 50 are mounted on the primary die pad 60. The mounting configuration of the insulation chip 50 on the primary die pad 60 is the same as the mounting configuration of the insulation chip 50 on the secondary die pad 70 in the embodiment described above.

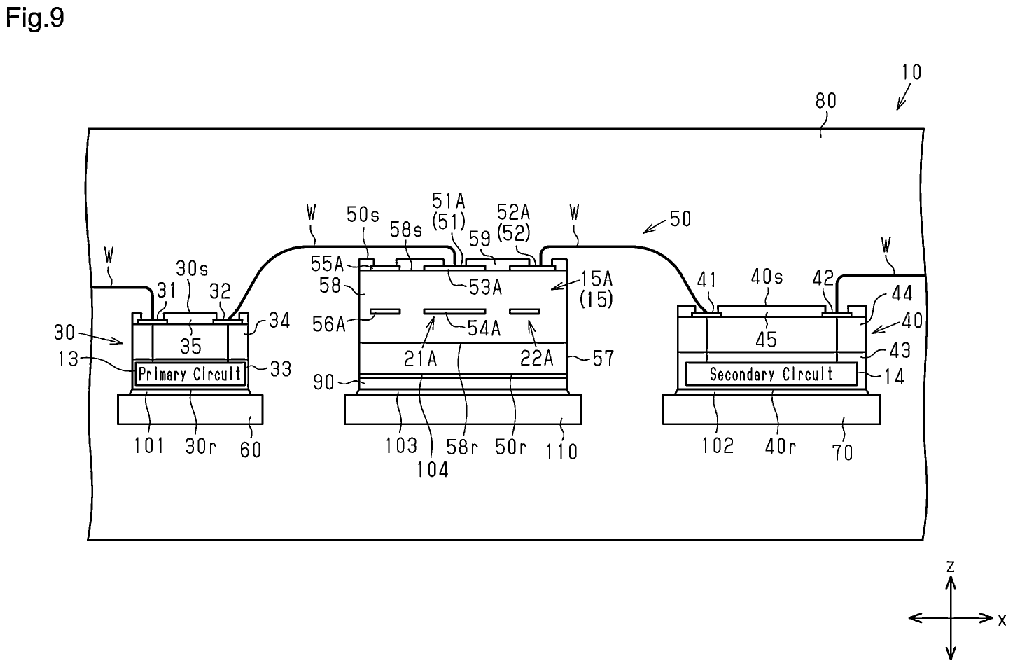

As shown in FIG. 9, the insulation chip 50 may be mounted on an intermediate die pad 110 that differs from the primary die pad 60 and the secondary die pad 70. The intermediate die pad 110 is electrically floating with respect to the primary die pad 60 and the secondary die pad 70. In other words, the insulation chip 50 is mounted on an electrically floating mount frame (intermediate die pad 110). The intermediate die pad 110 corresponds to a “mount frame” and a “third mount frame.”

The intermediate die pad 110 may be, for example, formed simultaneously with the die pads 60 and 70 from the same material as the die pads 60 and 70. The material forming the intermediate die pad 110 may be changed in any manner and may be, for example, formed from a material that differs from that of the die pads 60 and 70. In an example, the intermediate die pad 110 may be formed from ceramics such as alumina or an insulation material such as glass. The intermediate die pad 110 may be formed from a resin material.

In the example shown in FIG. 9, the insulating substrate 90 is bonded to the intermediate die pad 110 by the third bonding material 103. The insulation chip 50 is bonded to the insulating substrate 90 by the fourth bonding material 104.

Since the intermediate die pad 110 is electrically floating, the insulation chip 50 may be electrically connected to the intermediate die pad 110. Hence, the third bonding material 103 and the fourth bonding material 104 may be a conductive bonding material. Instead of arranging the insulating substrate 90 between the intermediate die pad 110 and the insulation chip 50, a semiconductor substrate may be used. The insulating substrate 90 may be omitted. That is, the insulation chip 50 may be bonded to the intermediate die pad 110 by the third bonding material 103. In this case, the third bonding material 103 may be a conductive bonding material or an insulative bonding material.

### Planar Shape of Capacitor in Modified Examples

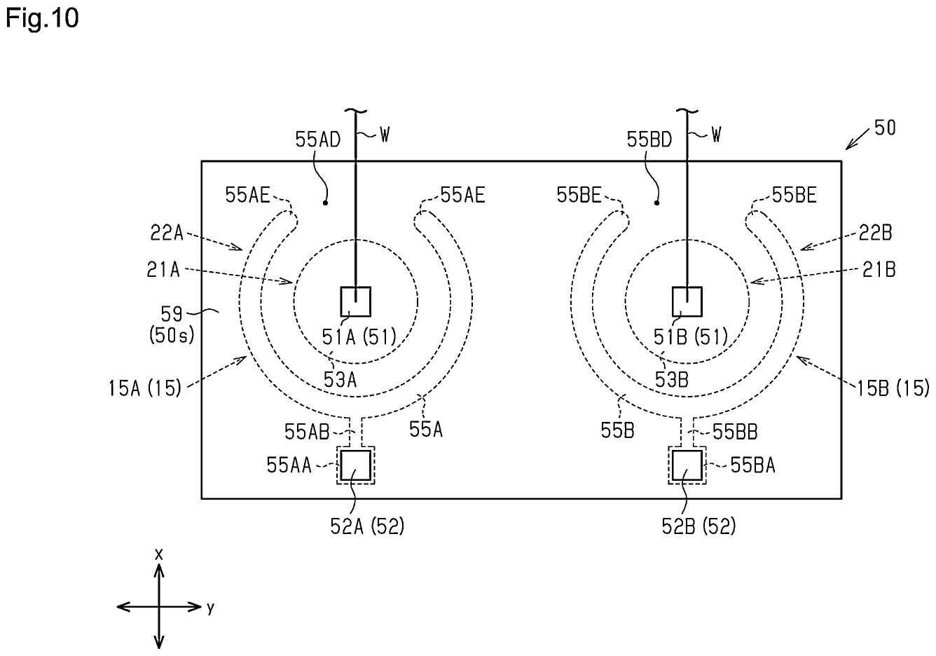

The shape of the second front electrode plates 55A and 55B of the capacitors 15A and 15B as viewed in the z-direction may be changed in any manner. In an example, as shown in FIG. 10, as viewed in the z-direction, the second front electrode plates 55A and 55B may have an open-annular shape including openings 55AD and 55BD.

The openings 55AD and 55BD and the second electrode pads 52A and 52B are located at opposite sides of the first electrode pads 51A and 51B. “The openings 55AD and 55BD and the second electrode pads 52A and 52B located at opposite sides of the first electrode pads 51A and 51B” means that the opening 55AD (55BD) and the second electrode pad 52A (52B) are located at opposite sides of the first electrode pad 51A (51B) in a straight line that extends through both the first electrode pad 51A (51B) and the second electrode pad 52A (52B). In the illustrated example, the openings 55AD and 55BD of the second front electrode plates 55A and 55B are formed in a portion of the second front electrode plates 55A and 55B located toward the first chip 30 (refer to FIG. 2) from the first electrode pads 51A and 51B.

Wires W that are connected to the first electrode pads 51A and 51B are connected to the first chip 30 (refer to FIG. 2). Thus, the wires W extend out from the first electrode pads 51A and 51B away from the second electrode pads 52A and 52B. Since the openings 55AD and 55BD and the second electrode pads 52A and 52B are located at opposite sides of the first electrode pads 51A and 51B, as viewed in the z-direction, the wires W connected to the first electrode pads 51A and 51B extend over the openings 55AD and 55BD. In other words, as viewed in the z-direction, the second front electrode plates 55A and 55B are located at a position differing from the position of the wires W connected to the first electrode pads 51A and 51B.

In the illustrated example, the second front electrode plates 55A and 55B include ends 55AE and 55BE defining the openings 55AD and 55BD. The ends 55AE and 55BE are bulged as viewed as viewed in the z-direction.

In this structure, as viewed in the z-direction, the wires W connected to the first front electrode plate 53A (53B) do not overlap the second front electrode plate 55A (55B). Thus, the wires W and the second front electrode plate 55A (55B), which have a large potential difference, are less likely to form a short-circuit. In addition, the end 55AE (55BE) of the second front electrode plate 55A (55B) includes a curved surface. Thus, an electric field is less likely to concentrate on the end 55AE (55BE).

The ends 55AE and 55BE of the second front electrode plates 55A and 55B may be changed in any manner. In an example, the ends 55AE and 55BE may include a flat distal surface. As viewed in the z-direction, the second back electrode plates 56A and 56B may have an open-annular shape that is open in conformance with the second front electrode plates 55A and 55B.

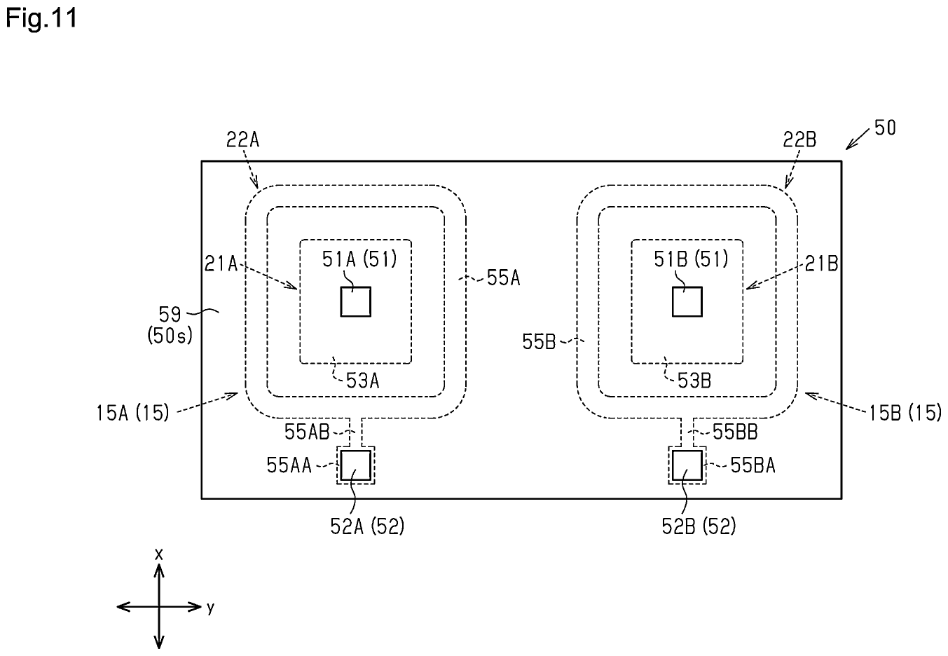

As viewed in the z-direction, the shapes of the first front electrode plates 53A and 53B and the first back electrode plates 54A and 54B of the capacitors 15A and 15B are not limited to a circle and may be changed in any manner. As viewed in the z-direction, the shape of the second front electrode plates 55A and 55B and the second back electrode plates 56A and 56B of the capacitors 15A and 15B are not limited to a circle and may be changed in any manner. In an example, as shown in FIG. 11, as viewed in the z-direction, the first front electrode plates 53A and 53B may be rectangular. In the illustrated example, each of the four corners of the first front electrode plates 53A and 53B is rounded to be curved.

As viewed in the z-direction, the second front electrode plates 55A and 55B may be rectangular-frame-shaped. In the illustrated example, each of the four corners of the second front electrode plates 55A and 55B is rounded to be curved.

The shape of the first front electrode plates 53A and 53B as viewed in the z-direction may be a polygon having five or more sides. In the same manner, the shape of the first back electrode plates 54A and 54B as viewed in the z-direction may be a polygon having five or more sides. The shape of the second front electrode plates 55A and 55B as viewed in the z-direction is a polygonal frame having five or more sides. In the same manner, the shape of the second back electrode plates 56A and 56B as viewed in the z-direction is a polygonal shape having five or more sides.

In the modified example shown in FIG. 11, as viewed in the z-direction, the first front electrode plates 53A and 53B may be circular. In this case, as viewed in the z-direction, the first back electrode plates 54A and 54B are circular.

In the modified example shown in FIG. 11, as viewed in the z-direction, the second front electrode plates 55A and 55B may have a closed-annular shape. In this case, as viewed in the z-direction, the second back electrode plates 56A and 56B have a closed-annular shape. Alternatively, as viewed in the z-direction, the second front electrode plates 55A and 55B may have an open-annular shape including the opening 55AD.

### Structure of Capacitor in Modified Examples

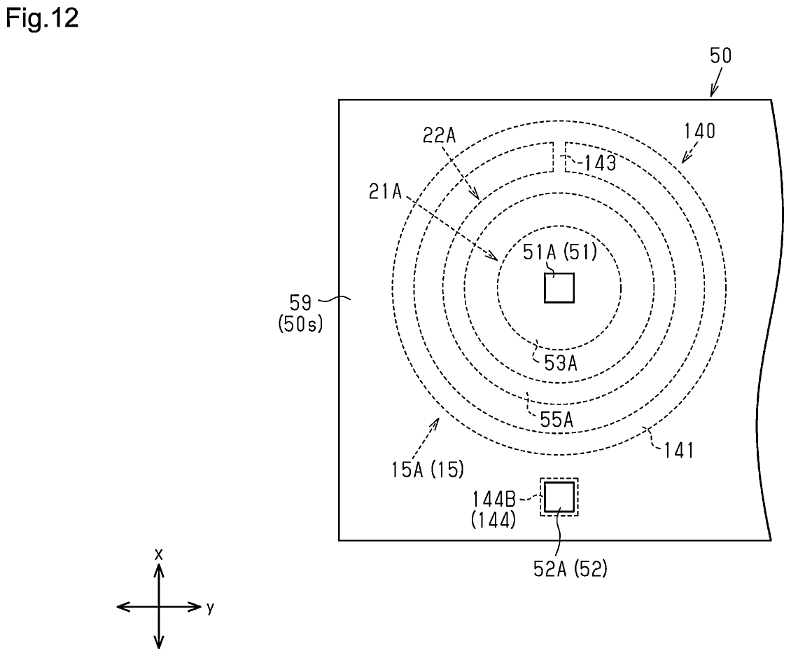

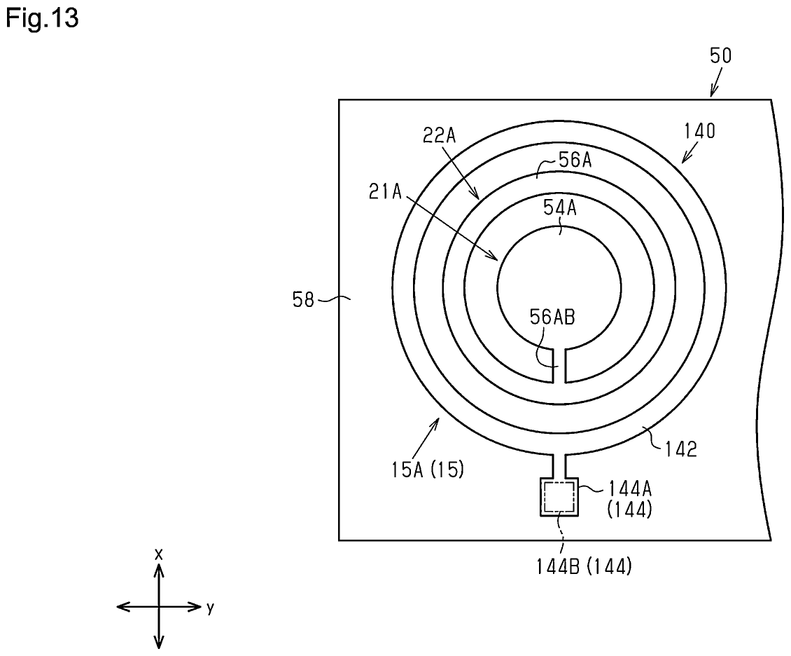

The capacitors 15A and 15B have a double insulation structure in which the first capacitors 21A and 21B and the second capacitors 22A and 22B are connected in series. However, there is no limit to this structure. In an example, as shown in FIGS. 12 and 13, the capacitor 15A may have a structure in which the first capacitor 21A, the second capacitor 22A, and a third capacitor 140 are connected in series.

The first capacitor 21A has the same structure as that of the embodiment described above. The second capacitor 22A differs from that of the embodiment in the structure of the second front electrode plate 55A. In the illustrated example, the second front electrode plate 55A does not include the electrode pad 55AA and the connector 55AB of the embodiment. Thus, as shown in FIG. 12, as viewed in the z-direction, the second front electrode plate 55A has a closed-annular shape.

As shown in FIGS. 12 and 13, the third capacitor 140 includes a third front electrode plate 141 and a third back electrode plate 142. The third front electrode plate 141 and the third back electrode plate 142 are formed from, for example, the same material as the electrode plates 53A, 54A, 55A, and 56A.

The third front electrode plate 141 has an inner diameter that is greater than the diameter of the second front electrode plate 55A. In the illustrated example, as viewed in the z-direction, the third front electrode plate 141 has a closed-annular shape.

As viewed in the z-direction, the third front electrode plate 141 is formed to surround the second front electrode plate 55A. The center of the third front electrode plate 141 coincides with the center of the first front electrode plate 53A. In other words, the third front electrode plate 141 and the first front electrode plate 53A are arranged to be concentric. That is, the third front electrode plate 141 is formed to be concentric with the first front electrode plate 53A and the second front electrode plate 55A. Although not shown in the drawings, the third front electrode plate 141 is aligned with the first front electrode plate 53A and the second front electrode plate 55A in the z-direction.

The third front electrode plate 141 may be greater than the second front electrode plate 55A in area as viewed in the z-direction. The area of the third front electrode plate 141 as viewed in the z-direction may be changed in any manner. In an example, the third front electrode plate 141 may be smaller than the second front electrode plate 55A in area as viewed in the z-direction.

In an example, the third front electrode plate 141 may be equal to the second front electrode plate 55A in area as viewed in the z-direction. When the difference in area as viewed in the z-direction between the third front electrode plate 141 and the second front electrode plate 55A is, for example, within 10% of the area of the second front electrode plate 55A as viewed in the z-direction, it is considered that the third front electrode plate 141 is equal to the second front electrode plate 55A in area as viewed in the z-direction.

The third front electrode plate 141 is electrically connected to the second front electrode plate 55A by a joint interconnect 143. The joint interconnect 143 and the second electrode pad 52A are located at opposite sides of the second front electrode plate 55A. The joint interconnect 143 may be changed in the circumferential direction of the second front electrode plate 55A.

As shown in FIG. 13, the third back electrode plate 142 has an inner diameter that is greater than the diameter of the second back electrode plate 56A. In the illustrated example, as viewed in the z-direction, the third back electrode plate 142 has a closed-annular shape.

As viewed in the z-direction, the third back electrode plate 142 is formed to surround the second back electrode plate 56A. The center of the third back electrode plate 142 coincides with the center of the first back electrode plate 54A. In other words, the third back electrode plate 142 and the first back electrode plate 54A are arranged to be concentric. That is, the third back electrode plate 142 is formed to be concentric with the first back electrode plate 54A and the second back electrode plate 56A. Although not shown in the drawings, the third back electrode plate 142 is aligned with the first back electrode plate 54A and the second back electrode plate 56A in the z-direction.

The third back electrode plate 142 may be greater than the second back electrode plate 56A in area as viewed in the z-direction. The area of the third back electrode plate 142 as viewed in the z-direction may be changed in any manner. In an example, the third back electrode plate 142 may be smaller than the second back electrode plate 56A in area as viewed in the z-direction.

In an example, the third back electrode plate 142 may be equal to the second back electrode plate 56A in area as viewed in the z-direction. When the difference in area as viewed in the z-direction between the third back electrode plate 142 and the second back electrode plate 56A is, for example, within 10% of the area of the second back electrode plate 56A as viewed in the z-direction, it is considered that the third back electrode plate 142 is equal to the second back electrode plate 56A in area as viewed in the z-direction.

In the illustrated example, the third back electrode plate 142 is equal in area to the third front electrode plate 141. When the difference in area between the third back electrode plate 142 and the third front electrode plate 141 is, for example, within 10% of the area of the third front electrode plate 141, it is considered that the third back electrode plate 142 is equal in area to the third front electrode plate 141.

The third back electrode plate 142 is electrically connected to the second electrode pad 52A by a joint interconnect 144. The joint interconnect 144 includes an interconnect portion 144A connected to the third back electrode plate 142 and a connection via 144B connected to the interconnect portion 144A and the second electrode pad 52A.

The interconnect portion 144A is connected to the third back electrode plate 142. As viewed in the z-direction, the interconnect portion 144A extends from the third back electrode plate 142 to a position where the second electrode pad 52A is formed. In the illustrated example, the interconnect portion 144A is formed integrally with the third back electrode plate 142.

The connection via 144B is arranged in the element insulation layer 58 (refer to FIG. 5) to connect the second electrode pad 52A and the interconnect portion 144A. The third capacitor 140 electrically connected to the second electrode pad 52A is electrically connected to the secondary circuit 14 (refer to FIG. 1).

In this structure, the three capacitors are connected in series to form an insulation structure. Thus, the insulation voltage of the insulation chip 50 is improved as compared to an insulation structure that is formed by two capacitors connected in series. When the insulation voltage of the insulation chip 50 is the same, the distance between the front electrode plate and the back electrode plate in the z-direction may be decreased. Consequently, the thickness TA of the element insulation layer 58 is decreased.

### Structure of Insulation Chip at Chip Back Surface in Modified Examples

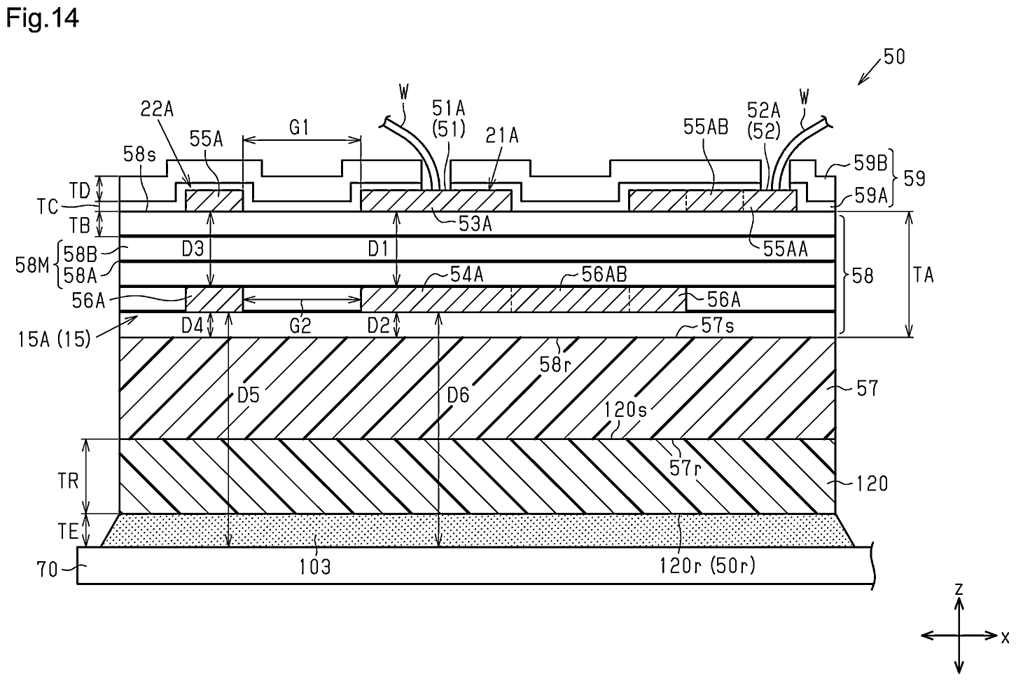

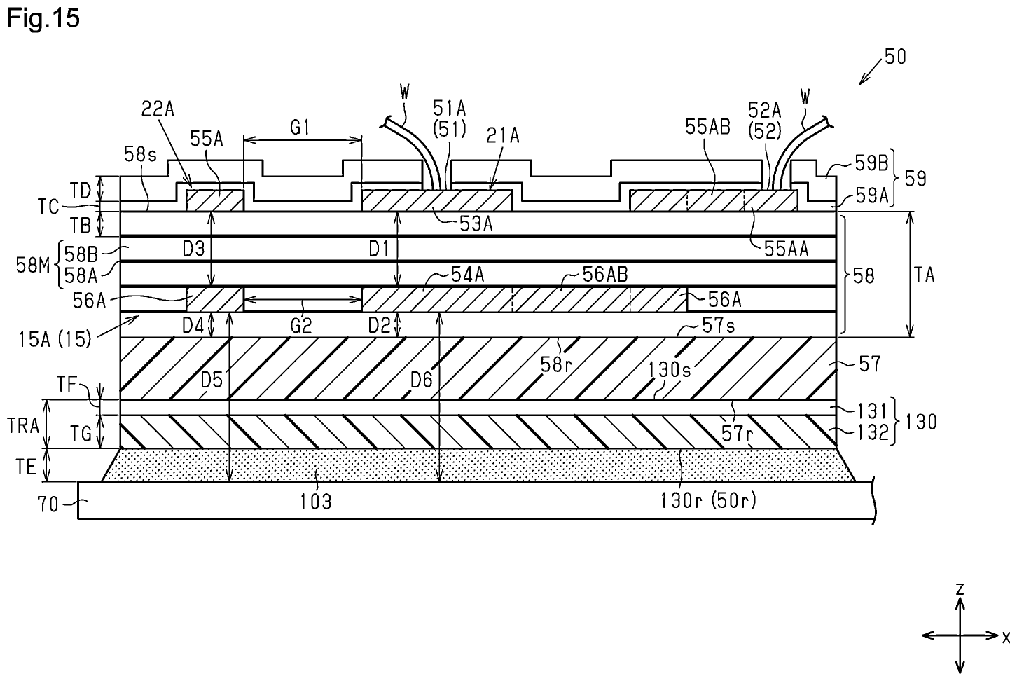

The structure of the insulation chip 50 at the chip back surface 50r may be changed, for example, as in a first example and a second example shown in FIGS. 14 and 15. As shown in FIGS. 14 and 15, the first electrode pads 51A and 51B, the second electrode pads 52A and 52B, the electrode plates 53A, 53B, 54A, 54B, 55A, 55B, 56A, and 56B, the element insulation layer 58, the protective film 59A, and the passivation film 59B each have the same structure as those in the first embodiment. In the modified examples shown in FIGS. 14 and 15, the insulating substrate 90 and the fourth bonding material 104 (refer to FIG. 5) are not arranged between the insulation chip 50 and the secondary die pad 70. The insulation chip 50 is directly bonded to the secondary die pad 70 by the third bonding material 103.

### First Example of Insulation Chip 50

As shown in FIG. 14, the insulation chip 50 includes a back insulation layer 120 arranged on the substrate back surface 57r of the substrate 57. The back insulation layer 120 is formed from an electrically-insulative material. In an example, the back insulation layer 120 is formed of a layer including, for example, SiO. The back insulation layer 120 is formed by, for example, applying a thermosetting organic siloxane polymer solution having Si—O—Si in the main chain to the substrate back surface 57r. Alternatively, the back insulation layer 120 may be formed of a layer, for example, including resin. Examples of the resin include an epoxy resin, a phenol resin, and a polyimide resin. In the first example, the back insulation layer 120 is formed on the entirety of the substrate back surface 57r. The back insulation layer 120 includes a front surface 120s and a back surface 120r facing opposite directions in the z-direction. The front surface 120s of the back insulation layer 120 is in contact with the substrate back surface 57r. The back surface 120r of the back insulation layer 120 includes the chip back surface 50r of the insulation chip 50.

As shown in FIG. 14, the insulation chip 50 is bonded to the secondary die pad 70 by the third bonding material 103. That is, in the first example, the insulating substrate 90 is not arranged between the insulation chip 50 and the secondary die pad 70. The third bonding material 103 bonds the back surface 120r of the back insulation layer 120 (the chip back surface 50r) and the secondary die pad 70. In the same manner as the embodiment described above, the third bonding material 103 includes an insulative bonding material.

The back insulation layer 120 has a thickness TR that is greater than a thickness TB of the insulation films 58M and less than the thickness TA of the element insulation layer 58. The thickness TR of the back insulation layer 120 is greater than a thickness TC of the protective film 59A and a thickness TD of the passivation film 59B. The thickness TR of the back insulation layer 120 is greater than the distance D2 between the first back electrode plate 54A and the back surface 58r of the element insulation layer 58 in the z-direction. The thickness TR of the back insulation layer 120 is greater than the distance D4 between the second back electrode plate 56A and the back surface 58r of the element insulation layer 58 in the z-direction. The thickness TR of the back insulation layer 120 is greater than a thickness TE of the third bonding material 103. In an example, the thickness TR of the back insulation layer 120 is in a range of 5 μm to 100 μm. The thickness TE of the third bonding material 103, which is less than the thickness TR of the back insulation layer 120, is less than 10 μm (approximately a few μm).

The thickness TR of the back insulation layer 120 is defined as the distance

between the front surface 120s and the back surface 120r of the back insulation layer 120 in the z-direction. The thickness TB of the insulation films 58M is defined as the distance between the front surface and the back surface of the insulation films 58M in the z-direction. In this modified example, the insulation films 58M include a first insulation film 58A and a second insulation film 58B. The thickness TB of the insulation films 58M is defined as the distance between a back surface of the first insulation film 58A and a front surface of the second insulation film 58B in the insulation films 58M in the z-direction. The thickness TC of the protective film 59A is defined as the distance between a front surface and a back surface of the protective film 59A in the z-direction. The front surface of the protective film 59A is in contact with a surface of the passivation film 59B. The back surface of the protective film 59A is in contact with the element insulation layer 58. The thickness TD of the passivation film 59B is defined as the distance between a front surface and a back surface of the passivation film 59B in the z-direction. The front surface of the passivation film 59B includes the chip front surface 50s of the insulation chip 50. The back surface of the passivation film 59B is in contact with the protective film 59A.

In this structure, the distances D5 and D6 between the secondary die pad 70 and the capacitor 15A in the z-direction are increased as compared to a structure in which an insulation chip does not include the back insulation layer 120 and is bonded to the secondary die pad 70 by the third bonding material 103. This improves the insulation voltage between the insulation chip 50 and the secondary die pad 70, thereby improving the insulation voltage of the signal transmission device 10.

In order to increase the thickness TE of the third bonding material 103, the volume of the third bonding material 103 needs to be increased. However, the third bonding material 103 applied to the secondary die pad 70 spreads when wet. Hence, to increase the thickness TE of the third bonding material 103, the third bonding material 103 may be increased in area as viewed in the z-direction and spread beyond the secondary die pad 70. The wet-spreading of the third bonding material 103 imposes limitations on the increasing of the thickness TE of the third bonding material 103.

In this regard, in the structure of the first example, the back insulation layer 120 is increased more readily than the third bonding material 103. Therefore, the thickness TR of the back insulation layer 120 is increased more readily than the thickness TE of the third bonding material 103. Thus, the distances D5 and D6 between the capacitor 15A and the secondary die pad 70 in the z-direction are readily increased.

When the back insulation layer 120 includes resin, the thickness TR of the back insulation layer 120 is readily increased as compared to when the back insulation layer 120 is formed of, for example, an oxide film.

The thickness TR of the back insulation layer 120 is greater than the distance D2 between the first back electrode plate 54A and the back surface 58r of the element insulation layer 58 in the z-direction and the distance D4 between the second back electrode plate 56A and the back surface 58r in the z-direction. Thus, the distances D5 and D6 between the capacitor 15A and the secondary die pad 70 in the z-direction may be increased without increasing the distances D3 and D4.

The thickness TR of the back insulation layer 120 may be changed in any manner. In an example, the thickness TR of the back insulation layer 120 may be greater than or equal to the thickness TA of the element insulation layer 58. The thickness TR of the back insulation layer 120 may be less than or equal to the thickness TE of the third bonding material 103 and the distances D2 and D4.

### Second Example of Insulation Chip 50

As shown in FIG. 15, the insulation chip 50 includes a back insulation layer 130 arranged on the substrate back surface 57r of the substrate 57. The back insulation layer 130 includes an oxide film 131 and an insulation layer 132. The back insulation layer 130 includes a front surface 130s and a back surface 130r facing opposite directions. The front surface 130s is in contact with the substrate back surface 57r. The back surface 130r includes the chip back surface 50r of the insulation chip 50.

The oxide film 131 is arranged on the substrate back surface 57r of the substrate 57. The oxide film 131 is formed from, for example, a material including SiO₂. The oxide film 131 is arranged on the entirety of the substrate back surface 57r.

The insulation layer 132 and the substrate 57 are arranged at opposite sides of the oxide film 131. The insulation layer 132 may be formed by applying a thermosetting organic siloxane polymer solution having Si—O—Si in the main chain to the oxide film 131. Thus, the insulation layer 132 is formed of a layer including SiO. The oxide film 131 includes a front surface and back surface facing opposite directions. The front surface of the oxide film 131 is in contact with the substrate 57. The insulation layer 132 is formed on the entirety of the back surface of the oxide film 131. Thus, the oxide film 131 is located between the substrate 57 and the insulation layer 132 in the z-direction. The oxide film 131 includes the front surface 130s of the back insulation layer 130. The insulation layer 132 includes the back surface 130r of the back insulation layer 130. In other words, the insulation layer 132 includes the chip back surface 50r of the insulation chip 50.

The insulation layer 132 may be formed from a material including resin. In this case, the insulation layer 132 is a resin layer. The insulation layer 132 (resin layer) may be formed from a material including, for example, one of an epoxy resin, a phenol resin, and a polyimide resin.

The back insulation layer 130 has a thickness TRA, that is, the total thickness of a thickness TF of the oxide film 131 and a thickness TG of the insulation layer 132. The thickness TRA of the back insulation layer 130 is greater than the thickness TE of the third bonding material 103. More specifically, the thickness TG of the insulation layer 132 is greater than the thickness TF of the oxide film 131. The thickness TF of the oxide film 131 is smaller than the thickness TE of the third bonding material 103. The thickness TG of the insulation layer 132 is equal to the thickness TE of the third bonding material 103. Therefore, the total thickness (the thickness TRA of the back insulation layer 130) of the thickness TF of the oxide film 131 and the thickness TG of the insulation layer 132 is greater than the thickness TE of the third bonding material 103.

The thickness TF of the oxide film 131 is defined as the distance between a surface (front surface) of the oxide film 131 that is in contact with the substrate back surface 57r of the substrate 57 and a surface (back surface) of the oxide film 131 that is in contact with the insulation layer 132 in the z-direction. The thickness TG of the insulation layer 132 is defined as the distance in the z-direction between a surface (front surface) of the insulation layer 132 that is in contact with the oxide film 131 and a surface (back surface) of the insulation layer 132 that is opposite to the front surface in the z-direction. The back surface of the insulation layer 132 includes the back surface 130r of the back insulation layer 130 (the chip back surface 50r of the insulation chip 50).

The thickness TRA of the back insulation layer 130 is greater than the thickness TC of the protective film 59A and the thickness TD of the passivation film 59B. The thickness TRA of the back insulation layer 130 is greater than the thickness TB of the insulation films 58M and less than the thickness TA of the element insulation layer 58. The thickness TRA of the back insulation layer 130 is greater than the distance D2 between the first back electrode plate 54A and the back surface 58r of the element insulation layer 58 in the z-direction. The thickness TRA of the back insulation layer 130 is greater than the distance D4 between the second back electrode plate 56A and the back surface 58r of the element insulation layer 58 in the z-direction.

The thickness TF of the oxide film 131 is less than the distances D2 and D4. The thickness TF of the oxide film 131 may be equal to the thickness TB of the insulation films 58M.

The thickness TG of the insulation layer 132 is greater than the thickness TC of the protective film 59A. The thickness TG of the insulation layer 132 is greater than or equal to the thickness TD of the passivation film 59B. The thickness TF of the oxide film 131 is greater than or equal to the thickness TC of the protective film 59A. The thickness TF of the oxide film 131 and the thickness TG of the insulation layer 132 may be changed in any manner.

In this structure, the distances D5 and D6 between the secondary die pad 70 and the capacitor 15A in the z-direction are increased as compared to a structure in which an insulation chip does not include the back insulation layer 130 and is bonded to the secondary die pad 70 by the third bonding material 103. This improves the insulation voltage between the insulation chip 50 and the secondary die pad 70, thereby improving the insulation voltage of the signal transmission device 10.

The thickness TG of the insulation layer 132, which is increased in thickness more readily than the oxide film 131, is greater than the thickness TF of the oxide film 131. Thus, the distances D5 and D6 between the secondary die pad 70 and the capacitor 15A are increased the z-direction.

The thickness TF of the oxide film 131, which is not readily increased in thickness, is smaller than the thickness TE of the third bonding material 103. This facilitates formation of the back insulation layer 130 including the oxide film 131 and the insulation layer 132.

In the modified examples of the insulation chip 50 shown in FIGS. 14 and 15, the insulating substrate 90 may be arranged between the insulation chip 50 and the secondary die pad 70. In this case, the structure for mounting the insulation chip 50 on the secondary die pad 70 via the insulating substrate 90 is the same as that in the embodiment.

### Structure of Element Insulation Layer in Modified Example

The structure of the insulation films 58M forming the element insulation layer 58 may be changed in any manner. In an example, as shown in FIGS. 14 and 15, the insulation films 58M include the first insulation film 58A and the second insulation film 58B formed on the first insulation film 58A. In this case, the electrode plates 53A, 53B, 54A, 54B, 55A, 55B, 56A, and 56B may be formed from a material including Cu.

The first insulation film 58A is, for example, an etch stop film, and is formed from a material including silicon nitride (SIN), SiC, nitrogen-added silicon carbide (SiCN), or the like. The first insulation film 58A for example, inhibits diffusion of Cu. That is, the first insulation film 58A is a Cu diffusion barrier film. The first insulation film 58A, for example, restricts warpage. More specifically, the first insulation film 58A is configured to warp in a direction opposite to a warping direction of the second insulation film 58B. In the modified examples shown in FIGS. 14 and 15, the first insulation film 58A is formed from a material including SiN. The second insulation film 58B is, for example, an interlayer insulation film and is an oxide film formed from a material including SiO₂. As shown in FIGS. 14 and 15, the thickness of the second insulation film 58B is greater than the thickness of the first insulation film 58A. The thickness of the first insulation film 58A may be in a range of 50 nm to 1000 nm. The thickness of the second insulation film 58B may be in a range of 500 nm to 5000 nm. In an example, the thickness of the first insulation film 58A is, for example, approximately 300 nm. The thickness of the second insulation film 58B is, for example, approximately 2000 nm.

The insulation chip 50 may include one or more resin layers as the element insulation layer 58 instead of the insulation films 58M. The resin layers may include a material including any one of polyimide resin, phenol resin, and epoxy resin.

### Usage of Insulation Chip in Modified Examples

The insulation chip 50 may be used in a device other than the signal transmission device 10 of the embodiment.

In an example, the insulation chip 50 may be used in a primary circuit module. The primary circuit module includes the first chip 30, the insulation chip 50, and an encapsulation resin that encapsulates the chips 30 and 50. The primary circuit module further includes the primary die pad 60 on which the first chip 30 and the insulation chip 50 are mounted. The first chip 30 is bonded to the primary die pad 60 by the first bonding material 101. The insulation chip 50 is bonded to the primary die pad 60 by the third bonding material 103.

The primary circuit module may include an intermediate die pad arranged separately from the primary die pad 60. The third bonding material 103 and the insulation chip 50 are bonded to the intermediate die pad. The first chip 30 is bonded to the primary die pad 60 by the first bonding material 101.

In another example, the insulation chip 50 may be used in a secondary circuit module. The secondary circuit module includes the second chip 40, the insulation chip 50, and an encapsulation resin that encapsulates the chips 40 and 50. The secondary circuit module further includes the secondary die pad 70 on which the second chip 40 and the insulation chip 50 are mounted. The second chip 40 is bonded to the secondary die pad 70 by the second bonding material 102. The insulation chip 50 is bonded to the secondary die pad 70 by the third bonding material 103.

The secondary circuit module may include an intermediate die pad arranged separately from the secondary die pad 70. The third bonding material 103 and the insulation chip 50 are bonded to the intermediate die pad. The second chip 40 is bonded to the secondary die pad 70 by the second bonding material 102.

### Structure of Signal Transmission Device in Modified Examples

The structure of the signal transmission device 10 may be changed in any manner.

In an example, the signal transmission device 10 may include the primary circuit module and the second chip 40. In this case, the second chip 40 may be mounted on the secondary die pad 70, and the secondary die pad 70 and the second chip 40 may be encapsulated by an encapsulation resin to form a module. In this case, the secondary circuit 14 (refer to FIG. 1) included in the second chip 40 corresponds to a “signal transmission circuit.” The second chip 40 corresponds to a “circuit chip.” The signal transmission device 10 corresponds to an “isolation module.”

In another example, the signal transmission device 10 may include the secondary circuit module and the first chip 30. In this case, the first chip 30 may be mounted on the primary die pad 60, and the primary die pad 60 and the first chip 30 may be encapsulated by an encapsulation resin to form a module. In this case, the primary circuit 13 (refer to FIG. 1) included in the first chip 30 corresponds to a “signal transmission circuit.” The first chip 30 corresponds to a “circuit chip.” The signal transmission device 10 corresponds to an “isolation module.”

The transmission direction of a signal in the signal transmission device 10 may be changed in any manner. In an example, the signal transmission device 10 may be configured to transmit a signal from the secondary circuit 14 to the primary circuit 13 through the capacitor 15. More specifically, when the secondary terminals 12 receive a signal (e.g., feedback signal) from the drive circuit, which is electrically connected to the secondary circuit 14 through the secondary terminals 12, the secondary circuit 14 transmits a signal to the primary circuit 13 through the capacitor 15. Then, the signal is output from the primary circuit 13 to the controller, which is electrically connected to the primary circuit 13 through the primary terminals 11. In another example, the signal transmission device 10 may be configured to bidirectionally transmit a signal between the primary circuit 13 and the secondary circuit 14. More specifically, the signal transmission device 10 may include the primary circuit 13 and the secondary circuit 14, which is configured to perform at least one of transmission of a signal and reception of a signal with the primary circuit 13 through the capacitor 15.

In the present disclosure, the term “on” includes the meaning of “above” in addition to the meaning of “on” unless otherwise clearly indicated in the context. Therefore, the phrase “first member formed on second member” is intended to mean that the first member may be formed on the second member in contact with the second member in one embodiment and that the first member may be located above the second member without contacting the second member in another embodiment. In other words, the term “on” does not exclude a structure in which another member is formed between the first member and the second member.

The z-direction as referred to in the present disclosure does not necessarily have to be the vertical direction and does not necessarily have to fully conform to the vertical direction. In the structures according to the present disclosure, “upward” and “downward” in the z-direction as referred to in the present description are not limited to “upward” and “downward” in the vertical direction. In an example, the x-direction may conform to the vertical direction. In another example, the y-direction may conform to the vertical direction.

In the present disclosure, “at least one of A and B” should be understood to mean “only A, only B, or both A and B.”

### CLAUSES

The technical aspects that are understood from the embodiment and the modified examples will be described below. To facilitate understanding without intention to limit, the reference signs of the elements in the embodiments are given to the corresponding elements in the clause with parentheses. The reference signs are used as examples to facilitate understanding, and the components in each clause are not limited to those components given with the reference signs.

### Clause 1

An insulation chip (50), including:
an element insulation layer (58) including a front surface (58s) and a back surface (58r); and
a first capacitor (21A, 21B) and a second capacitor (22A, 22B) formed on the element insulation layer (58), in which
the first capacitor (21A, 21B) includes a first front electrode plate (53A, 53B) and a first back electrode plate (54A, 54B) opposed to each other in a thickness-wise direction (z-direction) of the element insulation layer (58),
the second capacitor (22A, 22B) includes a second front electrode plate (55A, 55B) surrounding the first front electrode plate (53A, 53B) as viewed in the thickness-wise direction (z-direction) of the element insulation layer (58) and a second back electrode plate (56A, 56B) surrounding the first back electrode plate (54A, 54B) as viewed in the thickness-wise direction (z-direction) of the element insulation layer (58), the second front electrode plate (55A, 55B) and the second back electrode plate (56A, 56B) being opposed to each other in the thickness-wise direction (z-direction) of the element insulation layer (58), and
the first back electrode plate (54A, 54B) is electrically connected to the second back electrode plate (56A, 56B) in the element insulation layer (58).

### Clause 2

The insulation chip according to clause 1, in which as viewed in the thickness-wise direction (z-direction) of the element insulation layer (58), each of the first front electrode plate (53A, 53B) and the first back electrode plate (54A, 54B) is circular.

### Clause 3

The insulation chip according to clause 2, in which
the second front electrode plate (55A, 55B) is annular and has an inner diameter that is greater than a diameter of the first front electrode plate (53A, 53B),
the first front electrode plate (53A, 53B) and the second front electrode plate (55A, 55B) are arranged to be concentric,
the second back electrode plate (56A, 56B) is annular and has an inner diameter that is greater than a diameter of the first back electrode plate (54A, 54B), and
the first back electrode plate (54A, 54B) and the second back electrode plate (56A, 56B) are arranged to be concentric.

### Clause 4

The insulation chip according to clause 3, in which as viewed in the thickness-wise direction (z-direction) of the element insulation layer (58), each of the second front electrode plate (55A, 55B) and the second back electrode plate (56A, 56B) has a closed-annular shape.

### Clause 5

The insulation chip according to clause 3, in which as viewed in the thickness-wise direction (z-direction) of the element insulation layer (58), the second front electrode plate (55A, 55B) has an open-annular shape that includes an opening (55AD, 55BD).

### Clause 6

The insulation chip according to clause 5, in which the second front electrode plate (55A, 55B) includes an end (55AE, 55BE) defining the opening (55AD, 55BD), the end (55AE, 55BE) being bulged as viewed in the thickness-wise direction (z-direction) of the element insulation layer (58).

### Clause 7

The insulation chip according to any one of clauses 1 to 6, in which
as viewed in the thickness-wise direction (z-direction) of the element insulation layer (58), the first front electrode plate (53A, 53B) and the second front electrode plate (55A, 55B) are equal to each other in area, and
as viewed in the thickness-wise direction (z-direction) of the element insulation layer (58), the first back electrode plate (54A, 54B) and the second back electrode plate (56A, 56B) are equal to each other in area.

### Clause 8

The insulation chip according to any one of clauses 1 to 6, in which
as viewed in the thickness-wise direction (z-direction) of the element insulation layer (58), the first front electrode plate (53A, 53B) is greater in area than the second front electrode plate (55A, 55B), and
as viewed in the thickness-wise direction (z-direction) of the element insulation layer (58), the first back electrode plate (53A, 53B) is greater in area than the second back electrode plate (55A, 55B).

### Clause 9

The insulation chip according to any one of clauses 1 to 6, in which
as viewed in the thickness-wise direction (z-direction) of the element insulation layer (58), the second front electrode plate (55A, 55B) is greater in area than the first front electrode plate (53A, 53B), and
as viewed in the thickness-wise direction (z-direction) of the element insulation layer (58), the second back electrode plate (56A, 56B) is greater in area than the second back electrode plate (54A, 54B).

### Clause 10

The insulation chip according to any one of clauses 1 to 9, in which a minimum distance (G1) between the first front electrode plate (53A, 53B) and the second front electrode plate (55A, 55B) is greater than or equal to a minimum distance (D1) between the first front electrode plate (53A, 53B) and the first back electrode plate (54A, 54B).

### Clause 11

The insulation chip according to any one of clauses 1 to 10, further including:
a front protective layer (59) covering a front surface (58s) of the element insulation layer (58) and the second front electrode plate (55A, 55B),
in which the front protective layer (59) covers the first front electrode plate (53A, 53B) so that a surface of the first front electrode plate (53A, 53B) is partially exposed.

### Clause 12

The insulation chip according to clause 11, in which
the second capacitor (22A, 22B) includes a region (55AA, 55BA) formed integrally with the second front electrode plate (55A, 55B), and
as viewed in the thickness-wise direction (z-direction) of the element insulation layer (58), the region (55AA, 55BA) is located at a position differing from a position of the second front electrode plate (55A, 55B) and is exposed without being covered by the front protective layer (59).

### Clause 13

The insulation chip according to clause 11, further including:
an electrode pad (52A, 52B) electrically connected to the second front electrode plate and exposed from the front protective layer (59),
in which as viewed in the thickness-wise direction (z-direction) of the element insulation layer (58), the electrode pad (52A, 52B) is formed at a position separate from the second front electrode plate (55A, 55B).

### Clause 14

The insulation chip according to any one of clauses 1 to 13, further including:
a substrate (57) arranged on the back surface (58r) of the element insulation layer (58),
in which the element insulation layer (58) is further arranged between the first back electrode plate (54A, 54B) and the substrate (57) and between the second back electrode plate (56A, 56B) and the substrate (57).

### Clause 15

A signal transmission device (10), including:
a first chip (30) including a first circuit (13);
an insulation chip (50); and
a second chip (40) including a second circuit (14) configured to perform at least one of reception of a signal and transmission of a signal with the first circuit (13) through the insulation chip (50), in which
the insulation chip (50) includes
   an element insulation layer (58) including a front surface (58s) and a back surface (58r), and
   a first capacitor (21A, 21B) and a second capacitor (22A, 22B) formed on the element insulation layer (58),
the first capacitor (21A, 21B) includes a first front electrode plate (53A, 53B) and a first back electrode plate (54A, 54B) opposed to each other in a thickness-wise direction (z-direction) of the element insulation layer (58),
the second capacitor (22A, 22B) includes a second front electrode plate (55A, 55B) surrounding the first front electrode plate (53A, 53B) as viewed in the thickness-wise direction (z-direction) of the element insulation layer (58) and a second back electrode plate (56A, 56B) surrounding the first back electrode plate (54A, 54B) as viewed in the thickness-wise direction (z-direction) of the element insulation layer (58), the second front electrode plate (55A, 55B) and the second back electrode plate (56A, 56B) being opposed to each other in the thickness-wise direction (z-direction) of the element insulation layer (58), and
the first back electrode plate (54A, 54B) is electrically connected to the second back electrode plate (56A, 56B) in the element insulation layer (58).

### Clause 16

The signal transmission device according to clause 15, further including:
a first mount frame (60) on which the first chip (30) is mounted; and
a second mount frame (70) on which the second chip (40) is mounted,
in which the insulation chip (50) is mounted on the first mount frame (60) or the second mount frame (70) via an insulation member (90).

### Clause 17

The signal transmission device according to clause 15, further including:
a first mount frame (60) on which the first chip (30) is mounted;
a second mount frame (70) on which the second chip (40) is mounted; and
a third mount frame (110) on which the insulation chip (50) is mounted,
in which the third mount frame (110) is electrically floating with respect to both the first mount frame (60) and the second mount frame (70).

### Clause 18

The signal transmission device according to any one of clauses 15 to 17, in which
the signal transmission device (10) is configured to transmit the signal from the first circuit toward the second circuit through the first capacitor (21A, 21B) and the second capacitor (22A, 22B),
the first capacitor and the second capacitor each include a first signal capacitor (21A, 22A) and a second signal capacitor (21B, 22B),
the signal transmitted through the first capacitor (21A, 21B) and the second capacitor (22A, 22B) includes a first signal and a second signal,
the first signal is transmitted from the first circuit (13) toward the second circuit (14) through the first signal capacitor (21A, 22A), and
the second signal is transmitted from the first circuit (13) toward the second circuit (14) through the second signal capacitor (21B, 22B).

### Clause 19

The signal transmission device according to clause 16, in which
the insulation member (90) is bonded by a first insulative bonding material (103) to one of the first mount frame (60) and the second mount frame (70) on which the insulation chip (50) is mounted, and
the insulation chip (50) is bonded to the insulation member (90) by a second insulative bonding material (104).

### Clause 20

The insulation chip according to clause 14, in which
the substrate (57) includes a substrate front surface (57s) facing the element insulation layer (58) and a substrate back surface (57r) opposite to the substrate front surface (57s), and
a back insulation layer (120, 130) is arranged on the substrate back surface (57r).

### Clause 21

The insulation chip according to clause 20, in which the back insulation layer (120, 130) includes a resin.

### Clause 22

The insulation chip according to clause 20, in which the back insulation layer (130) includes an oxide film (131) arranged on the substrate back surface (57r) and an insulation layer (132) arranged on a side of the oxide film (131) opposite from the substrate (57).

### Clause 23

The insulation chip according to clause 22, in which a thickness (TG) of the insulation layer (132) is greater than a thickness (TF) of the oxide film (131).

### Clause 24

An isolation module, including:
the insulation chip (50) according to any one of clauses 1 to 14 and 20 to 23; and
a circuit chip (30/40) including a signal transmission circuit (13/14) electrically connected to the insulation chip (50).

The description above illustrates examples. One skilled in the art may recognize further possible combinations and replacements of the elements and methods (manufacturing processes) in addition to those listed for purposes of describing the techniques of the present disclosure. The present disclosure is intended to include any substitute, modification, changes included in the scope of the disclosure including the claims and the clauses.

### REFERENCE SIGNS LIST

10) signal transmission device
10A) signal transmission circuit
11) primary terminal
12) secondary terminal
13) primary circuit
14) secondary circuit
15, 15A, 15B) capacitor
16A, 16B) primary signal line
17A, 17B) secondary signal line
18A, 18B) connection signal line
21A, 21B) first capacitor
22A, 22B) second capacitor
23A, 23B) first electrode
24A, 24B) second electrode
25A, 25B) first electrode
26A, 26B) second electrode
30) first chip
30s) chip front surface
30r) chip back surface
31) first electrode pad
32) second electrode pad
33) first substrate
34) interconnect layer
40) second chip
40s) chip front substrate
40r) chip back surface
41) first electrode pad
42) second electrode pad
43) second substrate
44) interconnect layer
50) insulation chip
50s) insulation chip front surface
50r) insulation chip back surface
51, 51A, 51B) first electrode pad
52, 52A, 52B) second electrode pad
53A, 53B) first front electrode plate
54A, 54B) first back electrode plate
55A, 55B) second front electrode plate
55AA, 55BA) electrode pad
55AB, 55BB) connector
55AD, 55BD) opening
55AE, 55BE) end
56A, 56B) second front electrode plate
56AB, 56BB) joint interconnect
57) substrate
57s) substrate front surface
57r) substrate back surface
58) element insulation layer
58s) front surface
58r) back surface
58A) first insulation film
58B) second insulation film
59) front protective layer
59A) protective film
59B) passivation film
60) primary die pad
70) secondary die pad
80) encapsulation resin
90) insulating substrate
90s) front surface
90r) back surface
101) first bonding material
102) second bonding material
103) third bonding material
104) fourth bonding material
110) intermediate die pad
120) back insulation layer
120s) front surface
120r) back surface
130) back insulation layer
130s) front surface
130r) back surface
131) oxide film
132) insulation layer
140) third capacitor
141) third front electrode plate
142) third back electrode plate
143) joint interconnect
144) joint interconnect
144A) interconnect portion
144B) connection via
W) wire
G1) distance between first front electrode plate and second front electrode plate
G2) distance between first back electrode plate and second back electrode plate
D1) distance between first back electrode plate and first back electrode plate
D2) distance between first back electrode plate and element insulation layer
D3) distance between second front electrode plate and second back electrode plate
D4) distance between second back electrode plate and element insulation layer
D5) distance between first back electrode plate and secondary die pad
D6) distance between second back electrode plate and secondary die pad
TA) thickness of element insulation layer
TB) thickness of insulation film
TC) thickness of protection film
TD) thickness of passivation film
TE) thickness of third bonding material
TF) thickness of oxide film
TG) thickness of insulation layer
TR, TRA) thickness of back insulation layer
TS) thickness of insulating substrate

1. An insulation chip, comprising:
an element insulation layer including a front surface and a back surface; and
a first capacitor and a second capacitor formed on the element insulation layer, wherein
the first capacitor includes a first front electrode plate and a first back electrode plate opposed to each other in a thickness-wise direction of the element insulation layer,
the second capacitor includes a second front electrode plate surrounding the first front electrode plate as viewed in the thickness-wise direction of the element insulation layer and a second back electrode plate surrounding the first back electrode plate as viewed in the thickness-wise direction of the element insulation layer, the second front electrode plate and the second back electrode plate being opposed to each other in the thickness-wise direction of the element insulation layer, and
the first back electrode plate is electrically connected to the second back electrode plate in the element insulation layer.

2. The insulation chip according to claim 1, wherein as viewed in the thickness-wise direction of the element insulation layer, each of the first front electrode plate and the first back electrode plate is circular.

3. The insulation chip according to claim 2, wherein
the second front electrode plate is annular and has an inner diameter that is greater than a diameter of the first front electrode plate,
the first front electrode plate and the second front electrode plate are arranged to be concentric,
the second back electrode plate is annular and has an inner diameter that is greater than a diameter of the first back electrode plate, and
the first back electrode plate and the second back electrode plate are arranged to be concentric.

4. The insulation chip according to claim 3, wherein as viewed in the thickness-wise direction of the element insulation layer, each of the second front electrode plate and the second back electrode plate has a closed-annular shape.

5. The insulation chip according to claim 3, wherein as viewed in the thickness-wise direction of the element insulation layer, the second front electrode plate has an open-annular shape that includes an opening.

6. The insulation chip according to claim 5, wherein the second front electrode plate includes an end defining the opening, the end being bulged as viewed in the thickness-wise direction of the element insulation layer.

7. The insulation chip according to claim 1, wherein
as viewed in the thickness-wise direction of the element insulation layer, the first front electrode plate and the second front electrode plate are equal to each other in area, and
as viewed in the thickness-wise direction of the element insulation layer, the first back electrode plate and the second back electrode plate are equal to each other in area.

8. The insulation chip according to claim 1, wherein
as viewed in the thickness-wise direction of the element insulation layer, the first front electrode plate is greater in area than the second front electrode plate, and
as viewed in the thickness-wise direction of the element insulation layer, the first back electrode plate is greater in area than the second back electrode plate.

9. The insulation chip according to claim 1, wherein
as viewed in the thickness-wise direction of the element insulation layer, the second front electrode plate is greater in area than the first front electrode plate, and
as viewed in the thickness-wise direction of the element insulation layer, the second back electrode plate is greater in area than the first back electrode plate.

10. The insulation chip according to claim 1, wherein a minimum distance between the first front electrode plate and the second front electrode plate is greater than or equal to a minimum distance between the first front electrode plate and the first back electrode plate.

11. The insulation chip according to claim 1, further comprising:
a front protective layer covering a front surface of the element insulation layer and the second front electrode plate,
wherein the front protective layer covers the first front electrode plate so that a surface of the first front electrode plate is partially exposed.

12. The insulation chip according to claim 11, wherein
the second capacitor includes a region formed integrally with the second front electrode plate, and
as viewed in the thickness-wise direction of the element insulation layer, the region is located at a position differing from a position of the second front electrode plate and is exposed without being covered by the front protective layer.

13. The insulation chip according to claim 11, further comprising:
an electrode pad electrically connected to the second front electrode plate and exposed from the front protective layer,
wherein as viewed in the thickness-wise direction of the element insulation layer, the electrode pad is formed at a position separate from the second front electrode plate.

14. The insulation chip according to claim 1, further comprising:
a substrate arranged on the back surface of the element insulation layer,
wherein the element insulation layer is further arranged between the first back electrode plate and the substrate and between the second back electrode plate and the substrate.

15. A signal transmission device, comprising:
a first chip including a first circuit;
an insulation chip; and
a second chip including a second circuit configured to perform at least one of reception of a signal and transmission of a signal with the first circuit through the insulation chip, wherein
the insulation chip includes
an element insulation layer including a front surface and a back surface, and
a first capacitor and a second capacitor formed on the element insulation layer,
the first capacitor includes a first front electrode plate and a first back electrode plate opposed to each other in a thickness-wise direction of the element insulation layer,
the second capacitor includes a second front electrode plate surrounding the first front electrode plate as viewed in the thickness-wise direction of the element insulation layer and a second back electrode plate surrounding the first back electrode plate as viewed in the thickness-wise direction of the element insulation layer, the second front electrode plate and the second back electrode plate being opposed to each other in the thickness-wise direction of the element insulation layer, and
the first back electrode plate is electrically connected to the second back electrode plate in the element insulation layer.

16. The signal transmission device according to claim 15, further comprising:
a first mount frame on which the first chip is mounted; and
a second mount frame on which the second chip is mounted,
wherein the insulation chip is mounted on the first mount frame or the second mount frame via an insulation member.

17. The signal transmission device according to claim 15, further comprising:
a first mount frame on which the first chip is mounted;
a second mount frame on which the second chip is mounted; and
a third mount frame on which the insulation chip is mounted,
wherein the third mount frame is electrically floating with respect to both the first mount frame and the second mount frame.

18. The signal transmission device according to claim 15, wherein
the signal transmission device is configured to transmit the signal from the first circuit toward the second circuit through the first capacitor and the second capacitor,
the first capacitor and the second capacitor each include a first signal capacitor and a second signal capacitor,
the signal transmitted through the first capacitor and the second capacitor includes a first signal and a second signal,
the first signal is transmitted from the first circuit toward the second circuit through the first signal capacitor, and
the second signal is transmitted from the first circuit toward the second circuit through the second signal capacitor.
